(19) United States
(12) Patent Application Publication
(10) Pub. No.: US 2026/0020341 A1
(43) Pub. Date: Jan. 15, 2026

(54) SEMICONDUCTOR DEVICE AND METHOD OF FABRICATING THE SAME

(71) Applicant: Samsung Electronics Co., Ltd., Suwon-si (KR)

(72) Inventors: Mingyu SONG, Suwon-si (KR); Jongyong SON, Suwon-si (KR); Suehye PARK, Suwon-si (KR); Juyoun KIM, Suwon-si (KR); Hyung Jong LEE, Suwon-si (KR)

(73) Assignee: Samsung Electronics Co., Ltd., Suwon-si (KR)

(21) Appl. No.: 19/025,298

(22) Filed: Jan. 16, 2025

(30) Foreign Application Priority Data
Jul. 9, 2024 (KR) 10-2024-0090612

(51) Int. Cl. H10D 84/90; H10D 89/10

(52) U.S. Cl. CPC H10D 84/929; H10D 84/953; H10D 84/959; H10D 89/10

(57) ABSTRACT

A semiconductor device may include a substrate including a first active pattern and a second active pattern, which are spaced apart from each other in a first direction parallel to a top surface of the substrate, a device isolation layer between the first and second active patterns, a first source/drain pattern disposed on the first active pattern, a second source/drain pattern disposed on the second active pattern, a first active contact disposed on the first and second source/drain patterns, a barrier pattern interposed between the first active contact and the first source/drain pattern and between the first active contact and the second source/drain pattern and extended into a space between the first active contact and the device isolation layer, and an air gap interposed between the first active contact and the barrier pattern. The first active contact may be electrically connected to the first and second source/drain patterns.

### CROSS-REFERENCE TO RELATED APPLICATION

This application claims priority from Korean Patent Application No. 10-2024-0090612, filed on Jul. 9, 2024, in the Korean Intellectual Property Office, and all the benefits accruing therefrom under 35 U.S.C. § 119, the entire contents of which are hereby incorporated by reference.

### TECHNICAL FIELD

Apparatuses and methods consistent with the present disclosure relate to semiconductor devices, more specifically, to semiconductor devices including field effect transistors and methods of fabricating the same.

### BACKGROUND

Semiconductor devices may include integrated circuits configured with metal-oxide-semiconductor field-effect transistors (MOS-FETs). To meet increasing demands for semiconductor devices with a small pattern size and a reduced design rule, the MOS-FETs are being aggressively scaled down. The scale-down of the MOS-FETs may lead to deterioration in operational properties of the semiconductor devices. Therefore, research is being conducted to overcome technical limitations associated with the scale-down of the semiconductor devices and to realize high-performance semiconductor devices.

### SUMMARY

At least some embodiments of the present disclosure provide a semiconductor device with improved electrical characteristics and a method of fabricating the same.

At least some embodiments of the present disclosure provide a semiconductor device including: a substrate including a first active pattern and a second active pattern, which are spaced apart from each other in a first direction parallel to a top surface of the substrate, a device isolation layer between the first and second active patterns, a first source/drain pattern disposed on the first active pattern, a second source/drain pattern disposed on the second active pattern, a first active contact disposed on the first and second source/drain patterns, a barrier pattern interposed between the first active contact and the first source/drain pattern and between the first active contact and the second source/drain pattern and extended into a space between the first active contact and the device isolation layer, and an air gap interposed between the first active contact and the barrier pattern. The first active contact may be electrically connected to the first and second source/drain patterns.

At least some embodiments of the present disclosure provide a semiconductor device including: a substrate including a first active pattern and a second active pattern, which are spaced apart from each other in a first direction parallel to a top surface of the substrate, a device isolation layer between the first and second active patterns, a first source/drain pattern disposed on the first active pattern, a second source/drain pattern disposed on the second active pattern, a first active contact disposed on the first and second source/drain patterns, a barrier pattern interposed between the first active contact and the first source/drain pattern and between the first active contact and the second source/drain pattern, and an air gap interposed between the first active contact and the barrier pattern. The first active contact may include a first body portion on the first active pattern, a second body portion on the second active pattern, and a third body portion on the device isolation layer. The air gap may be interposed between the third body portion and the device isolation layer.

At least some embodiments of the present disclosure provide a semiconductor device including: a substrate including a first active pattern and a second active pattern, which are spaced apart from each other in a first direction parallel to a top surface of the substrate, a device isolation layer between the first and second active patterns, a first source/drain pattern disposed on the first active pattern, a second source/drain pattern disposed on the second active pattern, a first channel pattern disposed on the first active pattern and connected to the first source/drain pattern, a second channel pattern disposed on the second active pattern and connected to the second source/drain pattern, a first active contact disposed on the first and second source/drain patterns, a barrier pattern interposed between the first active contact and the first source/drain pattern and between the first active contact and the second source/drain pattern, and an air gap interposed between the first active contact and the device isolation layer. Each of the first and second channel patterns may include a plurality of semiconductor patterns, which are spaced apart from each other in a second direction perpendicular to the top surface of the substrate, and the first active contact may be electrically connected to the first and second source/drain patterns.

### BRIEF DESCRIPTION OF THE FIGURES

The accompanying drawings are included to provide a further understanding of the embodiments of the present disclosure, and are incorporated in and constitute a part of this specification. In the drawings:

FIGS. 1 to 3 are schematic diagrams illustrating logic cells of a semiconductor device, consistent with some embodiments of the present disclosure.

FIG. 4 is a plan view illustrating a semiconductor device, consistent with some embodiments of the present disclosure.

FIGS. 5A to 5E illustrate sectional views taken along lines A-A′, B-B′, C-C′, D-D′, and E-E′ of FIG. 4, consistent with some embodiments of the present disclosure.

FIGS. 6A, 7A, 8A, 9A, 10A, 11A, 12A, 13A, 14A, 15A, 16A, and 17A are sectional views illustrating a method of fabricating a semiconductor device, taken along the line A-A′ of FIG. 4, consistent with some embodiments of the present disclosure.

FIGS. 6B, 7B, 8B, 9B, 10B, 11B, 12B, 13B, 14B, 15B, 16B, and 17B are sectional views illustrating a method of fabricating a semiconductor device, taken along the line B-B′ of FIG. 4, consistent with some embodiments of the present disclosure.

FIGS. 6C, 7C, 8C, 9C, 10C, 11C, 12C, 13C, 14C, 15C, 16C, and 17C are sectional views illustrating a method of fabricating a semiconductor device, taken along the line C-C″ of FIG. 4, consistent with some embodiments of the present disclosure.

FIGS. 6D, 7D, 8D, 9D, 10D, 11D, 12D, 13D, 14D, 15D, 16D, and 17D are sectional views illustrating a method of fabricating a semiconductor device, taken along the line D-D′ of FIG. 4, consistent with some embodiments of the present disclosure.

FIGS. 6E, 7E, 8E, 9E, 10E, 11E, and 17E are sectional views illustrating a method of fabricating a semiconductor device, taken along the line E-E′ of FIG. 4, consistent with some embodiments of the present disclosure.

### DETAILED DESCRIPTION

Example embodiments of the present disclosure will now be described more fully with reference to the accompanying drawings, in which example embodiments are shown.

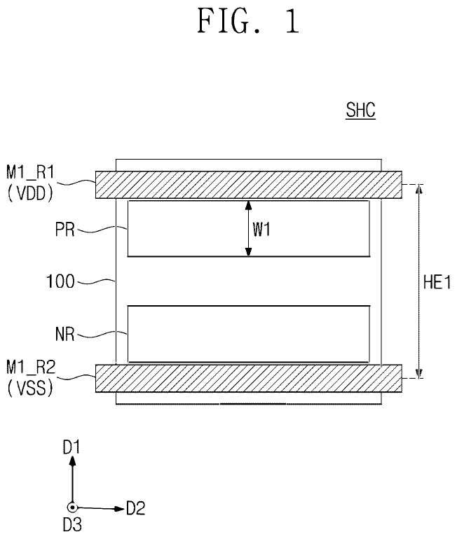

FIGS. 1 to 3 are schematic diagrams illustrating logic cells of a semiconductor device, consistent with some embodiments of the present disclosure.

Referring to FIG. 1, a single height cell SHC may be provided. In detail, a first power line M1_R1 and a second power line M1_R2 may be provided on a substrate 100. The first power line M1_R1 may be a conduction path to which a drain voltage VDD (e.g., a power voltage) may be provided. The second power line M1_R2 may be a conduction path to which a source voltage VSS (e.g., a ground voltage) may be provided.

The single height cell SHC may be defined between the first power line M1_R1 and the second power line M1_R2. The single height cell SHC may include a PMOSFET region PR and a NMOSFET region NR. In other words, the single height cell SHC may have a CMOS structure provided between the first power line M1_R1 and the second power line M1_R2.

Each of the PMOSFET region PR and NMOSFET region NR may have a first width W1 in a first direction D1 parallel to a top surface of the substrate 100. A length of the single height cell SHC in the first direction D1 may be defined as a first height HE1. The first height HE1 may be substantially equal to a distance (e.g., a pitch) between the first power line M1_R1 and the second power line M1_R2.

The single height cell SHC may constitute a single logic cell. In the present disclosure, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

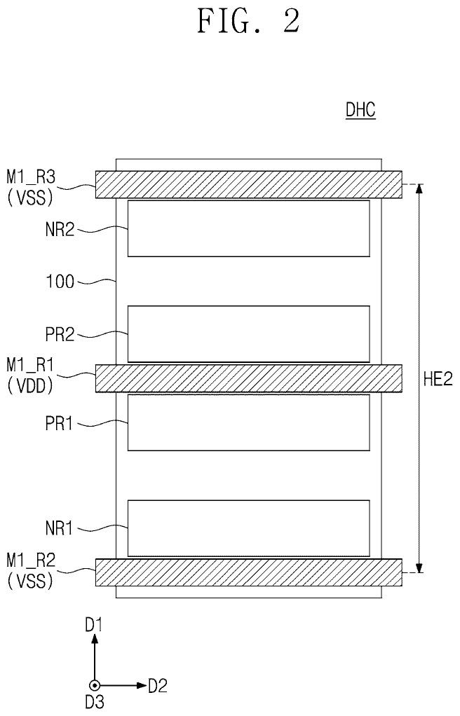

Referring to FIG. 2, a double height cell DHC may be provided. In detail, a first power line M1_R1, a second power line M1_R2, and a third power line M1_R3 may be provided on the substrate 100. The first power line M1_R1 may be disposed between the second power line M1_R2 and the third power line M1_R3. The third power line M1_R3 may be a conduction path to which the source voltage VSS is provided.

The double height cell DHC may be defined between the second power line M1_R2 and the third power line M1_R3. The double height cell DHC may include a first PMOSFET region PR1, a second PMOSFET region PR2, a first NMOSFET region NR1, and a second NMOSFET region NR2.

In some embodiments, the first NMOSFET region NR1 may be adjacent to the second power line M1_R2, the second NMOSFET region NR2 may be adjacent to the third power line M1_R3, the first and second PMOSFET regions PR1 and PR2 may be adjacent to the first power line M1_R1. When viewed in plan, the first power line M1_R1 may be disposed between the first and second PMOSFET regions PR1 and PR2, respectively.

A length of the double height cell DHC in the first direction D1 may be defined as a second height HE2. The second height HE2 may be about two times the first height HE1 of FIG. 1. The first and second PMOSFET regions PR1 and PR2, respectively, of the double height cell DHC may collectively operate as a single PMOSFET region.

In some embodiments, the double height cell DHC shown in FIG. 2 may be referred to as a multi-height cell. Although not illustrated, it should be appreciated that a multi-height cell may include a triple height cell whose cell height is about three times that of the single height cell SHC.

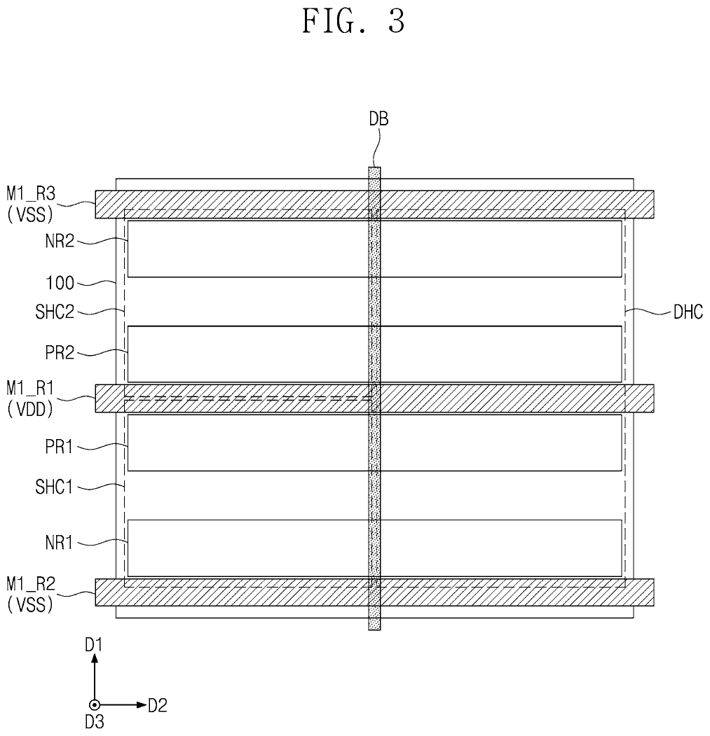

Referring to FIG. 3, a first single height cell SHC1, a second single height cell SHC2, and a double height cell DHC may be two-dimensionally arranged on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2, respectively, in a second direction D2.

In some embodiments, a division structure DB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the division structure DB.

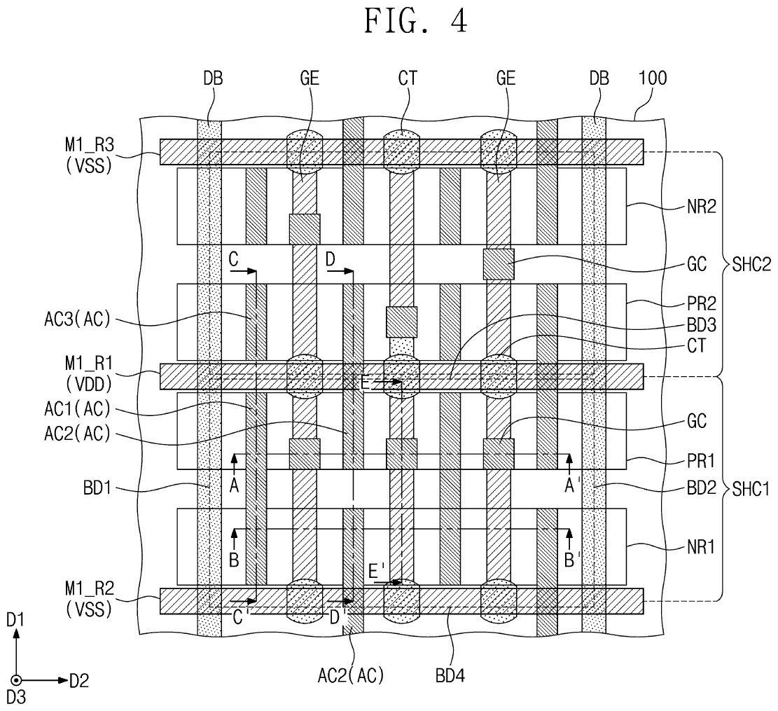

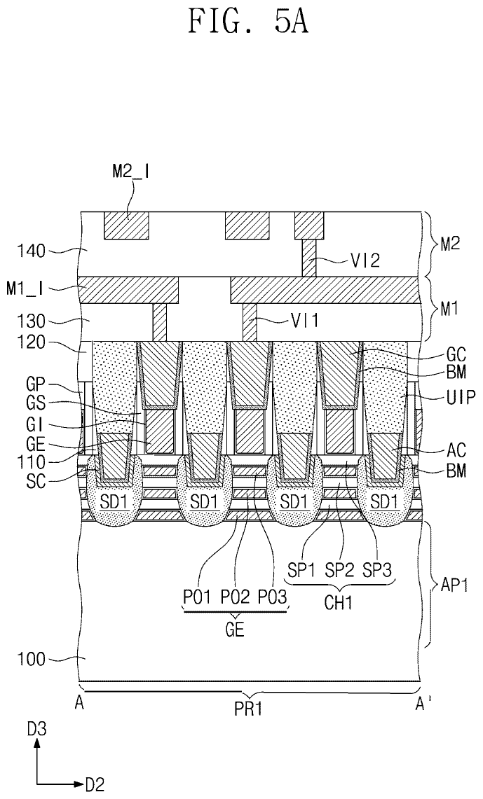

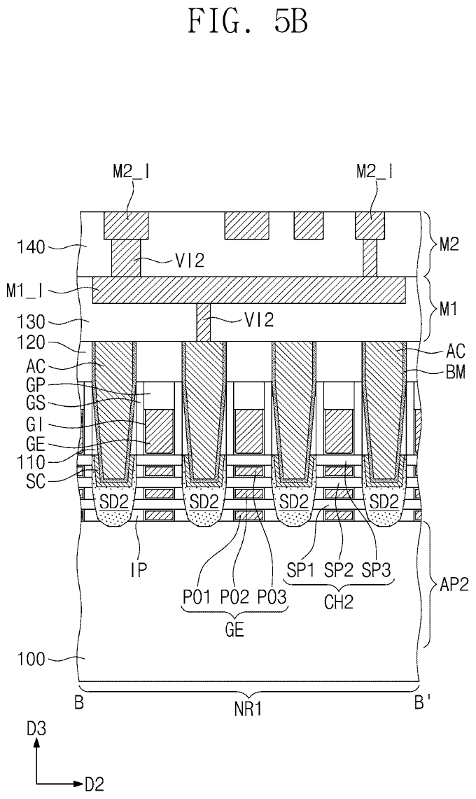

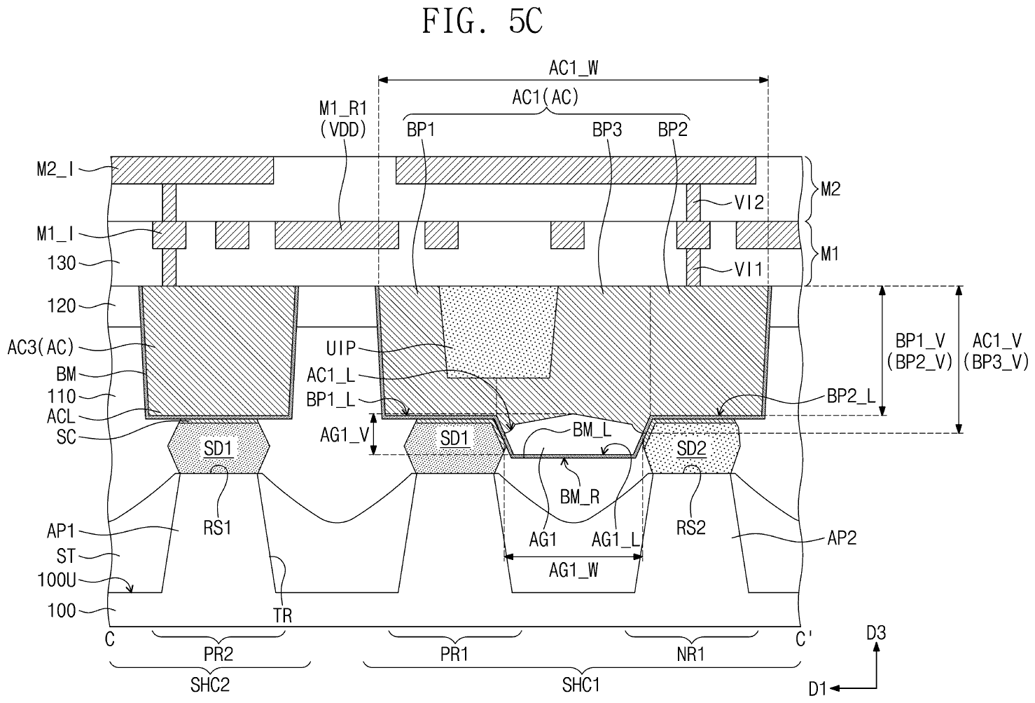

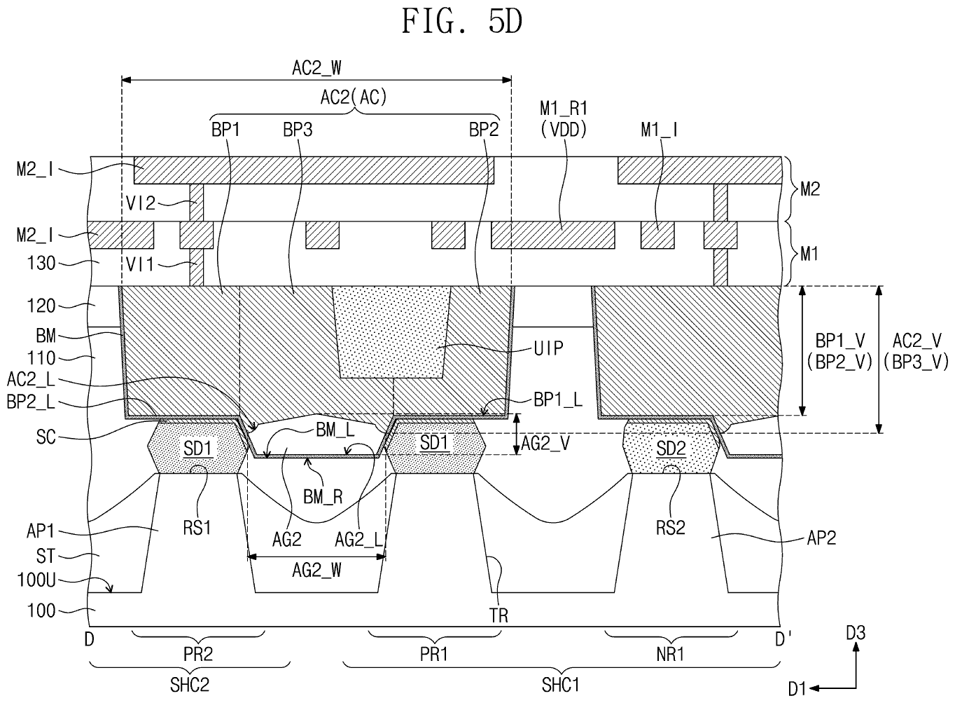

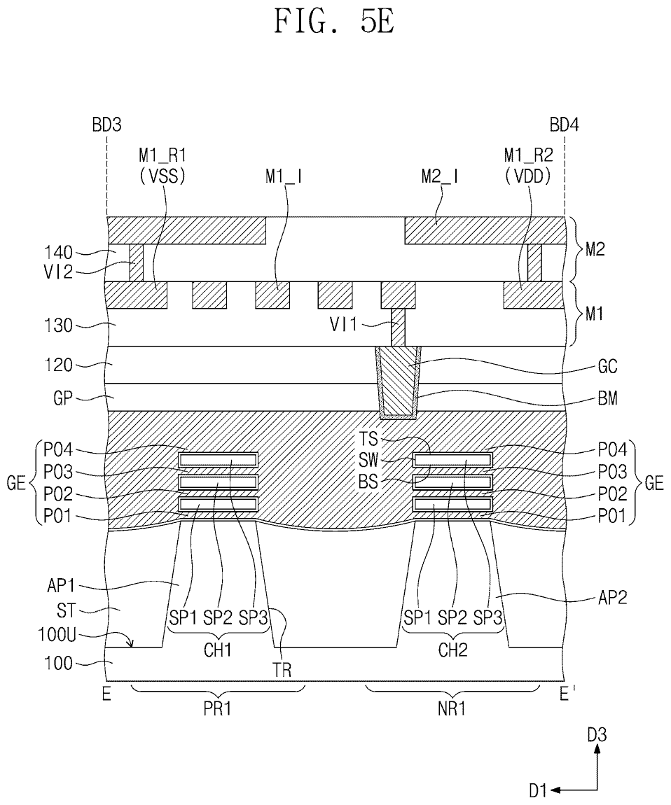

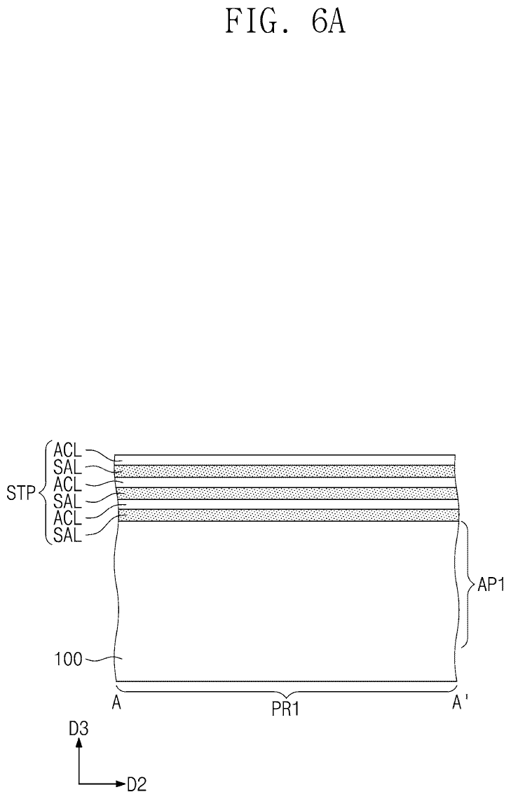

FIG. 4 is a plan view illustrating a semiconductor device, consistent with some embodiments of the present disclosure. FIGS. 5A to 5E are sectional views taken along lines A-A′, B-B′, C-C′, D-D′, and E-E′ of FIG. 4.

Referring to FIG. 4 and FIGS. 5A to 5E, the first and second single height cells SHC1 and SHC2, respectively, may be provided on substrate 100. Logic transistors constituting a logic circuit may be disposed on each of the first and second single height cells SHC1 and SHC2. The substrate 100 may be a semiconductor substrate, which is made of silicon, germanium, silicon-germanium, or a compound semiconductor material.

In some embodiments, substrate 100 may have a first PMOSFET region PR1, a second PMOSFET region PR2, a first NMOSFET region NR1, and a second NMOSFET region NR2. The first PMOSFET region PR1, the second PMOSFET region PR2, the first NMOSFET region NR1, and the second NMOSFET region NR2 may be active regions. Each of the first PMOSFET region PR1, the second PMOSFET region PR2, the first NMOSFET region NR1, and the second NMOSFET region NR2, may be extended in a second direction D2, which is parallel to a top surface 100U of the substrate 100 and is not parallel to the first direction D1.

Reference is now made to FIG. 5C, which illustrates a sectional view along line C-C′ of FIG. 4, consistent with some embodiments of the present disclosure. A first active pattern AP1 (e.g., FIGS. 5A, 5C) and a second active pattern AP2 (e.g., FIGS. 5B, 5C) may be defined by a trench TR (e.g., FIG. 5C), which is formed in an upper portion of the substrate 100. The first active pattern AP1 may be provided on each of the first and second PMOSFET regions PR1 and PR2 (e.g., FIG. 4). The second active pattern AP2 may be provided on each of the first and second NMOSFET regions NR1 and NR2 (e.g., FIG. 4). The first and second active patterns AP1 and AP2, respectively, may be extended along the second direction D2. The first and second active patterns AP1 and AP2 may be vertically protruding portions of the substrate 100, which are extended along a third direction D3 perpendicular to the top surface of the substrate 100.

Referring to FIG. 5C, a device isolation layer ST may fill the trench TR. The device isolation layer ST may include a silicon oxide layer. The device isolation layer ST may be disposed between the first active pattern AP1 and the second active pattern AP2.

In some embodiments, first source/drain patterns SD1 may be provided on each of the first and second PMOSFET regions PR1 and PR2 (e.g., FIG. 4), respectively. The first source/drain patterns SD1 may be provided on the first active pattern AP1. The first source/drain patterns SD1 may be impurity regions of a first conductivity type (e.g., p-type). Referring to FIG. 5E, a first channel pattern CH1 (e.g., FIGS. 5A, 5E) may be interposed between a pair of the first source/drain patterns SD1, which are adjacent to each other along the second direction D2, and may be provided on the first active pattern AP1. The first channel pattern CH1 may include semiconductor patterns SP1, SP2, and SP3, which are provided on the first active pattern AP1 and are spaced apart from each other along the third direction D3. The pair of the first source/drain patterns SD1 may be connected to the semiconductor patterns SP1, SP2, and SP3 of the first channel pattern CH1.

Second source/drain patterns SD2 (e.g., FIGS. 5B, 5C) may be provided on each of the first and second NMOSFET regions NR1 and NR2 (e.g., FIG. 4). The second source/drain patterns SD2 may be provided on the second active pattern AP2. The second source/drain patterns SD2 may be impurity regions of a second conductivity type, and here, the second conductivity type may be an n-type, different from the first conductivity type. A second channel pattern CH2 (e.g., FIGS. 5B, 5E) may be interposed between a pair of the second source/drain patterns SD2, which are adjacent to each other in the second direction D2, and may be disposed on the second active pattern AP2. The second channel pattern CH2 may include semiconductor patterns SP1, SP2, and SP3, which are provided on the second active pattern AP2 and are spaced apart from each other in the third direction D3. The pair of the second source/drain patterns SD2 may be connected to the semiconductor patterns SP1, SP2, and SP3 of the second channel pattern CH2.

The first and second source/drain patterns SD1 and SD2 may be epitaxial patterns, formed by a selective epitaxial growth (SEG) process. As an example, the first and second source/drain patterns SD1 and SD2 may have top surfaces that are coplanar with top surfaces of the first and second channel patterns CH1 and CH2. As another example, the top surfaces of the first and second source/drain patterns SD1 and SD2 may be higher than the top surfaces of the first and second channel patterns CH1 and CH2.

The first source/drain pattern SD1 may be formed of or include a semiconductor material (e.g., SiGe) whose lattice constant is larger than a lattice constant of the first channel pattern CH1. In this case, the pair of the first source/drain patterns SD1 may exert a compressive stress on the first channel patterns CH1 therebetween. In some embodiments, the second source/drain pattern SD2 may be formed of or include a semiconductor material (e.g., Si or SiC) whose lattice constant is smaller than or equal to a lattice constant of the second channel pattern CH2. In the case where the second source/drain pattern SD2 may include a semiconductor material with a lattice constant smaller than the lattice constant of the second channel pattern CH2, the pair of the second source/drain patterns SD2 may exert a tensile stress on the second channel pattern CH2 therebetween.

Gate electrodes GE (e.g., FIGS. 4, 5A, 5B, 5E) may be extended along the first direction D1 to cross the first and second active patterns AP1 and AP2. The gate electrodes GE may be vertically overlapped with the first and second channel patterns CH1 and CH2. Each of the gate electrodes GE may be provided to enclose a top surface and opposite side surfaces of each of the first and second channel patterns CH1 and CH2.

Referring to FIG. 4, the first single height cell SHC1 may have a first border BD1 and a second border BD2, which are opposite to each other in the second direction D2. The first and second borders BD1 and BD2 may be extended in the first direction D1. The first single height cell SHC1 may have a third border BD3 and a fourth border BD4, which are opposite to each other along the first direction D1. The third and the fourth borders BD3 and BD4, respectively, may be extended along the second direction D2.

In some embodiments, one or more gate cutting patterns CT may be disposed on the third and the fourth borders BD3 and BD4, respectively, of the first single height cell SHC1. The gate cutting patterns CT may be disposed on a border of each of the first and second single height cells SHC1 and SHC2 extending along the second direction D2. When viewed in a plan view (e.g., FIG. 4), the gate cutting patterns CT on the third and the fourth borders BD3 and BD4 may be disposed to be overlapped with the gate electrodes GE, respectively. The gate cutting patterns CT may be formed of or include an insulating material (e.g., silicon oxide or silicon nitride).

The gate electrode GE on the first single height cell SHC1 may be separated from the gate electrode GE on the second single height cell SHC2 by the gate cutting pattern CT. The gate cutting pattern CT may be interposed between the gate electrodes GE, which are respectively placed on the first and second single height cells SHC1 and SHC2 that are aligned to each other in the first direction D1. That is, the gate electrode GE extending in the first direction D1 may be divided into a plurality of the gate electrodes GE by the gate cutting patterns CT.

The gate electrodes GE may be extended in the first direction D1 to cross the first and second channel patterns CH1 and CH2. Each of the gate electrodes GE may be vertically overlapped with the first and second channel patterns CH1 and CH2. Referring to FIGS. 5A, 5B, the gate electrode GE may include a first portion PO1 interposed between the active pattern AP1 or AP2 and a first semiconductor pattern SP1, a second portion PO2 interposed between the first semiconductor pattern SP1 and a second semiconductor pattern SP2, a third portion PO3 interposed between the second semiconductor pattern SP2 and a third semiconductor pattern SP3, and a fourth portion PO4 on the third semiconductor pattern SP3.

Referring to FIG. 5E, the gate electrode GE may be provided on a top surface TS, a bottom surface BS, and opposite side surfaces SW of each of the first to the third semiconductor patterns SP1, SP2, and SP3. That is, the transistor according to the present embodiment may be a three-dimensional field effect transistor (e.g., MBCFET or GAAFET) in which the gate electrode GE is provided to three-dimensionally surround the channel pattern.

Referring to FIGS. 5A, 5B, a pair of gate spacers GS may be disposed on opposite side surfaces, respectively, of the fourth portion PO4 of the gate electrode GE. The gate spacers GS may be extended along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described below. In some embodiments, the gate spacers GS may be formed of or include at least one of SiCN, SiCON, or SiN. In some embodiments, the gate spacers GS may have a multi-layered structure including at least two layers, each of which is made of SiCN, SiCON, or SiN.

A gate capping pattern GP may be provided on the gate electrode GE. The gate capping pattern GP may be extended along the gate electrode GE and along the first direction D1. The gate capping pattern GP may be formed of or include a material having an etch selectivity with respect to first and second interlayer insulating layers 110 and 120, which will be described below The gate capping pattern GP may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and the opposite side surfaces SW of each of the first to the third semiconductor patterns SP1, SP2, and SP3. The gate insulating layer GI may cover a top surface of the device isolation layer ST below the gate electrode GE.

The gate electrode GE may include a first metal pattern and a second metal pattern on the first metal pattern. The first metal pattern may be provided on the gate insulating layer GI and adjacent to the first to third semiconductor patterns SP1, SP2, and SP3. By adjusting a thickness and composition of the first metal pattern, it may be possible to realize a transistor having a desired threshold voltage. For example, the first to third portions PO1, PO2, and PO3 of the gate electrode GE may be composed of the first metal pattern. The first and second metal patterns may have different work functions from each other.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In some embodiments, the first metal pattern may further include carbon (C). The first metal pattern may include a plurality of metal layers which are stacked.

The second metal pattern may include a metal having a resistance lower than the first metal pattern. For example, the second metal pattern may include at least one metallic material, which is selected from the group consisting of tungsten (W), aluminum (Al), titanium (Ti), and tantalum (Ta). For example, the fourth portion PO4 of the gate electrode GE may include the first metal pattern and the second metal pattern on the first metal pattern.

Inner spacers IP (e.g., FIG. 5B) may be provided on the first and second NMOSFET regions NR1, NR2. The inner spacers IP may be interposed between the gate insulating layer GI and the second source/drain pattern SD2. The gate electrode GE may be spaced from the second source/drain pattern SD2 by the gate insulating layer GI and the isolation pattern IP. On the other hand, in the first and the second PMOSFET regions PR1, PR2, the insulation pattern IP may be omitted. A first interlayer insulating layer 110 (e.g., FIGS. 5A-5D) may be provided on the substrate 100. The first interlayer insulating layer 110 may cover the gate spacers GS and the first and second source/drain patterns SD1 and SD2. A top surface of the first interlayer insulating layer 110 may be substantially coplanar with top surfaces of the gate capping patterns GP and top surfaces of the gate spacers GS.

A second interlayer insulating layer 120 (e.g., FIGS. 5A-5E) may be disposed on the first interlayer insulating layer 110 to cover the gate capping patterns GP. A third interlayer insulating layer 130 (e.g., FIGS. 5A-5E) may be provided on the second interlayer insulating layer 120. A fourth interlayer insulating layer 140 (e.g., FIGS. 5A-5E) may be provided on the third interlayer insulating layer 130. In some embodiments, the first to fourth interlayer insulating layers 110 to 140 may include a silicon oxide layer.

A pair of division structures DB (e.g., FIG. 4) may be provided on both sides of each of the first and second single height cells SHC1 and SHC2 to be opposite to each other along the second direction D2. For example, the pair of division structures DB may be provided on the first and second borders BD1 and BD2 of the first single height cell SHC1, respectively. The division structure DB may be extended along the first direction D1 to be parallel or substantially parallel to the gate electrodes GE.

The division structure DB may be provided to penetrate the first and second interlayer insulating layers 110 and 120 and may be extended into the first and second active patterns AP1 and AP2. The division structure DB may be provided to penetrate an upper portion of each of the first and second active patterns AP1 and AP2, respectively. The division structure DB may electrically separate an active region of each of the first and second single height cells SHC1 and SHC2 from an active region of a neighboring cell.

In some embodiments, one or more active contacts AC may be provided to penetrate the first and second interlayer insulating layers 110 and 120, respectively, and may be electrically connected to the first and second source/drain patterns SD1 and SD2, respectively. Each of the active contacts AC may be provided between a pair of the gate electrodes GE. When viewed in a plan view, each of the active contacts AC may be a bar- or line-shaped pattern, which is extended in the first direction D1.

The active contacts AC (e.g., FIGS. 4, 5B-5D) may be a self-aligned contact formed in a self-aligned manner using the gate capping pattern GP and the gate spacer GS. For example, the active contacts AC may cover at least a portion of the side surface of the gate spacer GS. Although not shown, in certain embodiments, the active contacts AC may cover a portion of the top surface of the gate capping pattern GP.

Each of silicide patterns SC may be interposed between the active contacts AC and the first and second source/drain patterns SD1 and SD2. The active contacts AC may be electrically connected to the first and second source/drain patterns SD1 and SD2, respectively, through the silicide patterns SC. The silicide pattern SC may be formed of or include at least one of metal silicide materials (e.g., titanium silicide, tantalum silicide, tungsten silicide, nickel silicide, and cobalt silicide).

The active contacts AC may include a first active contact AC1, a second active contact AC2, and a third active contact AC3 (e.g., FIGS. 4, 5B-5D).

The first active contact AC1 may electrically connect the first source/drain pattern SD1 of the first PMOSFET region PR1 and the second source/drain pattern SD2 of the first NMOSFET region NR1, which are provided on the first single height cell SHC1, to each other. The first active contact AC1 may be extended from the second source/drain pattern SD2 of the first NMOSFET region NR1 to the first source/drain pattern SD1 of the first PMOSFET region PR1 along the first direction D1.

The second active contact AC2 may electrically connect the first source/drain pattern SD1 of the first PMOSFET region PR1 to the first source/drain pattern SD1 of the second PMOSFET region PR2. The second active contact AC2 may be extended from the first source/drain pattern SD1 of the first PMOSFET region PR1 to the first source/drain pattern SD1 of the second PMOSFET region PR2 in the first direction D1. The second active contact AC2 may be provided to cross a border (e.g., the third border BD3) between the first and second single height cells SHC1 and SHC2 and may be commonly coupled to the first PMOSFET region PR1 of the first single height cell SHC1 and the second PMOSFET region PR2 of the second single height cell SHC2.

Referring to FIGS. 5C and 5D, the first active contact AC1 may include a first body portion BP1 on the first source/drain pattern SD1, a second body portion BP2 on the second source/drain pattern SD2, and a third body portion BP3 on the device isolation layer ST. The third body portion BP3 may be interposed between the first and second body portions BP1 and BP2.

The second active contact AC2 may include the first body portion BP1 on the first source/drain pattern SD1 of the first PMOSFET region PR1, the second body portion BP2 on the first source/drain pattern SD1 of the second PMOSFET region PR2, and the third body portion BP3 on the device isolation layer ST. The third body portion BP3 may be interposed between the first and second body portions BP1 and BP2.

The third active contact AC3 may be provided on the first source/drain pattern SD1 of the second PMOSFET region PR2. In another embodiment, the third active contact AC3 may be provided on the second source/drain pattern SD2 of the second NMOSFET region NR2, which is placed on the second single height cell SHC2. The third active contact AC3 may be locally provided on a single active region and may not be used to connect adjacent ones of the active regions to each other.

When viewed in a plan view, a length of the third active contact AC3 along the first direction D1 may be shorter than a length of each of the first and second active contacts AC1 and AC2 along the first direction D1. For example, the length of the third active contact AC3 may be smaller than half of the length of each of the first and second active contacts AC1 and AC2. In some embodiments, the active contacts AC may be formed of or include at least one of metallic materials (e.g., aluminum, copper, tungsten, molybdenum, and cobalt).

Referring to FIG. 5E, in some embodiments, gate contacts GC may be provided to penetrate the second interlayer insulating layer 120 and the gate capping pattern GP, and may be electrically connected to the gate electrodes GE, respectively. In some embodiments, an upper insulating pattern UIP (e.g., FIGS. 5A, 5C, 5D) may be provided to fill an upper portion of each of the active contacts AC adjacent to the gate contact GC. A bottom surface of the upper insulating pattern UIP may be lower than a bottom surface of the gate contact GC. In other words, owing to the upper insulating pattern UIP, a top surface of the active contact AC, which is adjacent to the gate contact GC, may be formed at a level lower than the bottom surface of the gate contact GC. Accordingly, it may be possible to prevent the gate contact GC and the active contact AC, which are adjacent to each other, from being in contact with each other, and thereby to prevent a short circuit issue from occurring therebetween. In some embodiments, the gate contact GC may be formed of or include at least one of metallic materials (e.g., aluminum, copper, tungsten, molybdenum, and cobalt).

In some embodiments, a barrier pattern BM (e.g., FIGS. 5A-5E) may be provided to cover a side surface of the first and second active contact AC1 or AC2, respectively, or to cover side and bottom surfaces of the third active contact AC3. The barrier pattern BM may be provided to cover side and bottom surfaces of the gate contact GC. The barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

Referring back to FIG. 5C, the bottommost surface BM_L of the barrier pattern BM may be spaced apart from the bottommost surface AC1_L of the first active contact AC1 along the third direction D3. The barrier pattern BM may be interposed between the first active contact AC1 and the first source/drain pattern SD1 and between the first active contact AC1 and the second source/drain pattern SD2 and may be extended into a space between the first active contact AC1 and the device isolation layer ST. The barrier pattern BM may have a recess region BM_R, which is formed between the first and second source/drain patterns SD1 and SD2 and is recessed toward the device isolation layer ST.

A first air gap AG1 may be interposed between the first active contact AC1 and the device isolation layer ST (e.g., between the third body portion BP3 and the device isolation layer ST). The first air gap AG1 may be interposed between the barrier pattern BM and the first active contact AC1 (e.g., between the barrier pattern BM and the third body portion BP3). The first air gap AG1 may be disposed on the recess region BM_R of the barrier pattern BM. The bottommost surface AG1_L of the first air gap AG1 may be located at a level lower than the bottommost surface AC1_L of the first active contact AC1. The bottommost surface AG1_L of the first air gap AG1 may be spaced apart from the bottommost surface BP1_L of the first body portion and/or the bottommost surface BP2_L of the second body portion BP2 in the third direction D3. A length AG1_V of the first air gap AG1 in the third direction D3 may be smaller than a length AC1_V of the first active contact AC1 in the third direction D3 and may be smaller than each of lengths BP1_V, BP2_V, and BP3_V of the first to third body portions BP1, BP2, and BP3 along the third direction D3.

The first air gap AG1 may be interposed between the first and second source/drain patterns SD1 and SD2. A width AG1_W of the first air gap AG1 along the first direction D1 may be smaller than a width AC1_W of the first active contact AC1 along the first direction D1.

Referring back to FIG. 5D, the bottommost surface AC2_L of the second active contact AC2 may be spaced apart from the bottommost surface BM_L of the barrier pattern BM along the third direction D3. The barrier pattern BM may be interposed between the second active contact AC2 and the first source/drain pattern SD1 of the first PMOSFET region PR1 and between the second active contact AC2 and the second source/drain pattern SD2 of the second PMOSFET region PR2 and may be extended into a space between the second active contact AC2 and the device isolation layer ST. The barrier pattern BM may have a recess region BM_R, which is formed between the first source/drain patterns SD1 of the first and second PMOSFET regions PR1 and PR2 and is recessed toward the device isolation layer ST.

A second air gap AG2 may be interposed between the second active contact AC2 and the device isolation layer ST and may be extended to a space between the third body portion BP3 and the device isolation layer ST. The second air gap AG2 may be interposed between the barrier pattern BM and the second active contact AC2 (e.g., between the barrier pattern BM and the third body portion BP3). The second air gap AG2 may be disposed on the recess region BM_R of the barrier pattern BM. The bottommost surface AG_L of the second air gap AG2 may be located at a level lower than the bottommost surface AC2_L of the second active contact AC2. The bottommost surface AG2_L of the second air gap AG2 may be spaced apart from the bottommost surface BP1_L of the first body portion BP1 or the bottommost surface BP2_L of the second body portion BP2 in the third direction D3. A length AG2_V of the second air gap AG2 in the third direction D3 may be smaller than a length AC2_V of the second active contact AC2 in the third direction D3 and may be smaller than each of the lengths BP1_V, BP2_V, and BP3_V of the first to third body portions BP1, BP2, and BP3 in the third direction D3.

The second air gap AG2 may be interposed between the first source/drain pattern SD1 of the first PMOSFET region PR1 and the second source/drain pattern SD2 of the second PMOSFET region PR2. A width AG2_W of the second air gap AG2 along the first direction D1 may be smaller than a width AC2_W of the second active contact AC2 along the first direction D1.

In some embodiments of the present disclosure, air gap AG1 or AG2 may be interposed between the device isolation layer ST and the active contact (e.g., the first or second active contact AC1 or AC2), which is used to connect the source/drain patterns SD1 and SD2 to each other. In this case, since a conductive material for the active contact AC1 or AC2 is not provided in the air gap AG1 or AG2, a sectional area of the active contact (e.g., the first or second active contact AC1 or AC2) may be reduced. Accordingly, a parasitic capacitance between adjacent ones of the active contacts may be reduced, and a semiconductor device with improved electrical characteristics may be provided.

Referring back to FIG. 4 and FIGS. 5A to 5E, a first metal layer M1 may be provided in the third interlayer insulating layer 130. For example, the first metal layer M1 may include the first power line M1_R1, the second power line M1_R2, the third power line M1_R3, and first interconnection lines M1_I. The lines M1_R1, M1_R2, M1_R3, and M1_I of the first metal layer M1 may be extended along the second direction D2 and may be parallel to each other.

In detail, the first and second power lines M1_R1 and M1_R2, respectively, may be provided on the third and fourth borders BD3 and BD4 of the first single height cell SHC1, respectively. The first power line M1_R1 may be extended along the third border BD3 and in the second direction D2. The second power line M1_R2 may be extended along the fourth border BD4 and in the second direction D2.

The first metal layer M1 may further include first vias VI1. The first vias VI1 may be respectively provided below the M1_R1, M1_R2, M1_R3, and M1_I of the first metal layer M1. The active contact AC and the interconnection line of the first metal layer M1 may be electrically connected to each other through the first via VI1. The gate contact GC and the interconnection line of the first metal layer M1 may be electrically connected to each other through the first via VI1.

A second metal layer M2 may be provided in the fourth interlayer insulating layer 140. The second metal layer M2 may include a plurality of second interconnection lines M2_I. Each of the second interconnection lines M2_I of the second metal layer M2 may be a line-shaped or bar-shaped pattern that is extended along the first direction D1. In other words, the second interconnection lines M2_I may be extended along the first direction D1 to be parallel to each other.

The second metal layer M2 may further include second vias VI2, which are respectively provided below the second interconnection lines M2_I. The interconnection lines of the first and second metal layers M1 and M2 may be electrically connected to each other through the second via VI2.

The interconnection lines of the first metal layer M1 may be formed of or include a conductive material that is the same as or different from those of the second metal layer M2. For example, the interconnection lines of the first and second metal layers M1 and M2 may be formed of or include at least one of metallic materials (e.g., aluminum, copper, tungsten, molybdenum, and cobalt). Although not shown, a plurality of metal layers (e.g., M3, M4, M5, and so forth) may be additionally disposed on the fourth interlayer insulating layer 140. Each of the stacked metal layers may include interconnection lines, which are used as routing paths between cells.

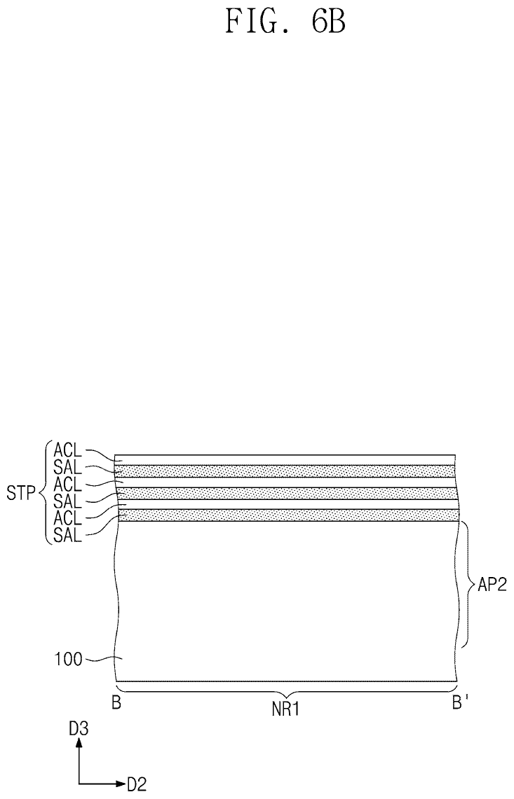

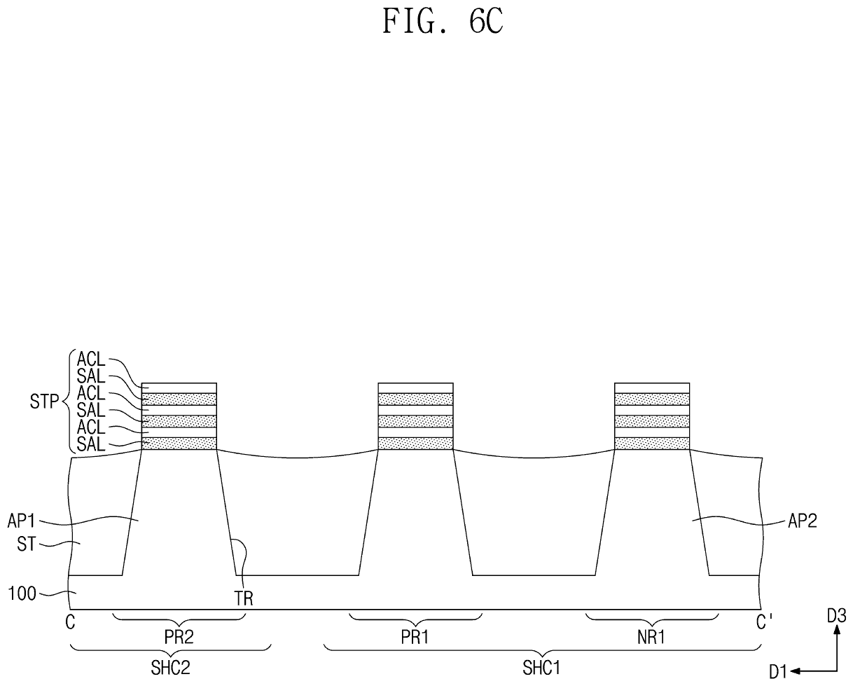

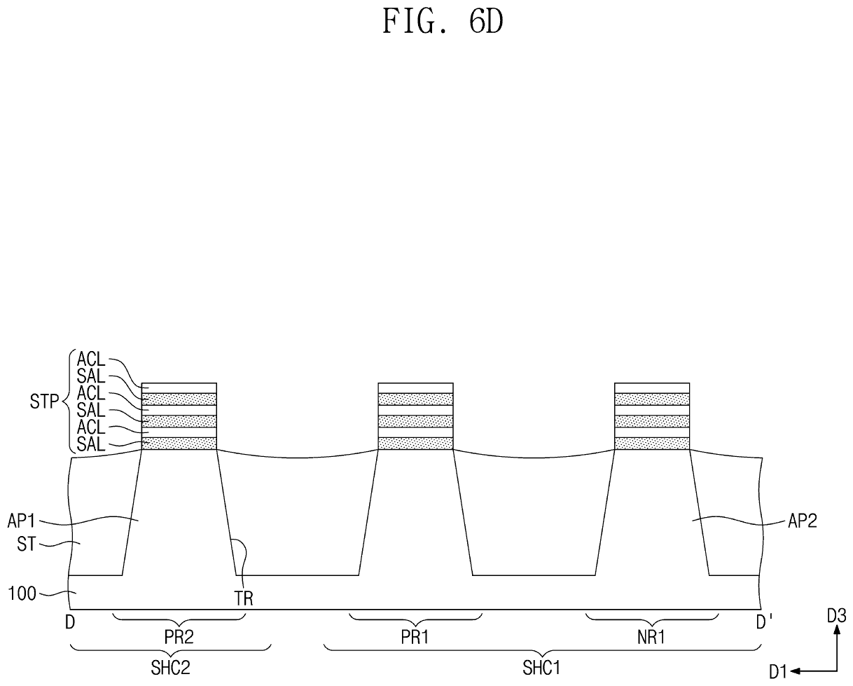

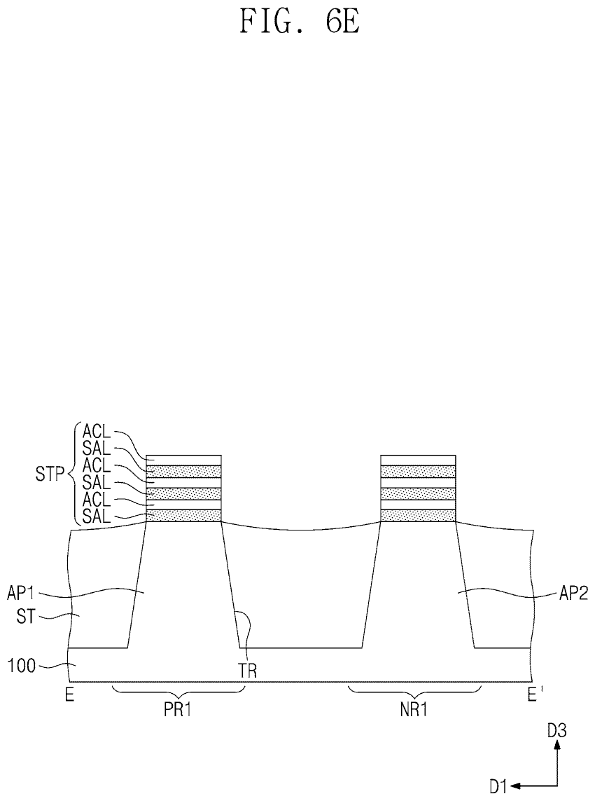

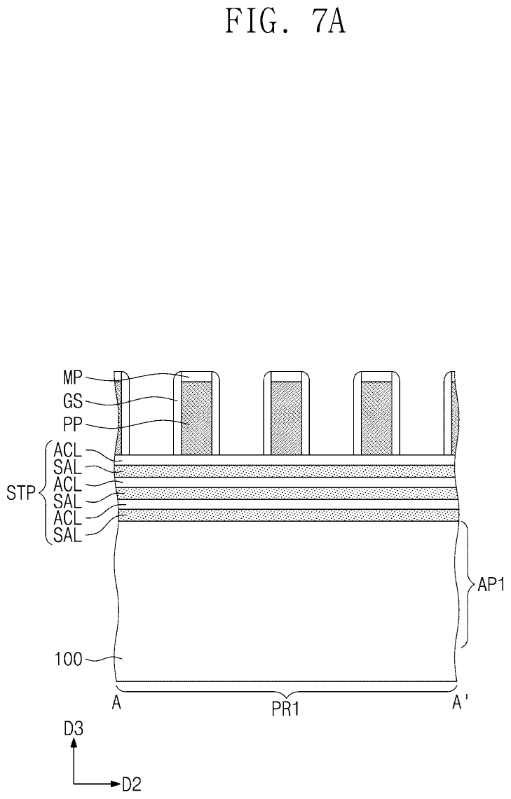

Reference is now made to FIGS. 6A, 7A, 8A, 9A, 10A, 11A, 12A, 13A, 14A, 15A, 16A, and 17A, which are sectional views taken along the line A-A′ of FIG. 4, consistent with embodiments of the present disclosure. For concise description, an element previously described with reference to FIGS. 1 to 5E may be identified by the same reference number without repeating an overlapping description thereof.

Referring to FIGS. 6A to 6E, the substrate 100 having the first PMOSFET region PR1, the second PMOSFET region PR2, the first NMOSFET region NR1, and the second NMOSFET region NR2 may be provided. The first NMOSFET region NR1 and the first PMOSFET region PR1 may define the first single height cell SHC1, and the second NMOSFET region NR2 and the second PMOSFET region PR2 may define the second single height cell SHC2.

The first and second active patterns AP1 and AP2 may be formed by patterning the substrate 100. The first active patterns AP1 may be formed on each of the first and second PMOSFET regions PR1 and PR2. The second active patterns AP2 may be formed on each of the first and second NMOSFET regions NR1 and NR2.

In some embodiments, the formation of the first and second active patterns AP1 and AP2 may include forming a mask pattern on the substrate and etching the substrate 100 using the mask pattern as an etch mask. As a result of the etching process, the trench TR may be formed to define the first active pattern AP1 and the second active pattern AP2.

First sacrificial layers SAL and active layers ACL may be formed on the substrate 100 and may be alternatingly stacked along the third direction D3 perpendicular to the top surface of the substrate 100. The first sacrificial layers SAL and the active layers ACL may be formed of or include at least one of silicon (Si), germanium (Ge), or silicon germanium (SiGe) and may be formed of different materials from each other. For example, the first sacrificial layers SAL may include silicon-germanium (SiGe), and the active layers ACL may include silicon (Si).

The device isolation layer ST may be formed to fill the trench TR. In detail, an insulating layer may be formed on the substrate 100 to cover the first and second active patterns AP1 and AP2 and stacking patterns STP. The device isolation layer ST may be formed by recessing the insulating layer to expose the stacking patterns STP.

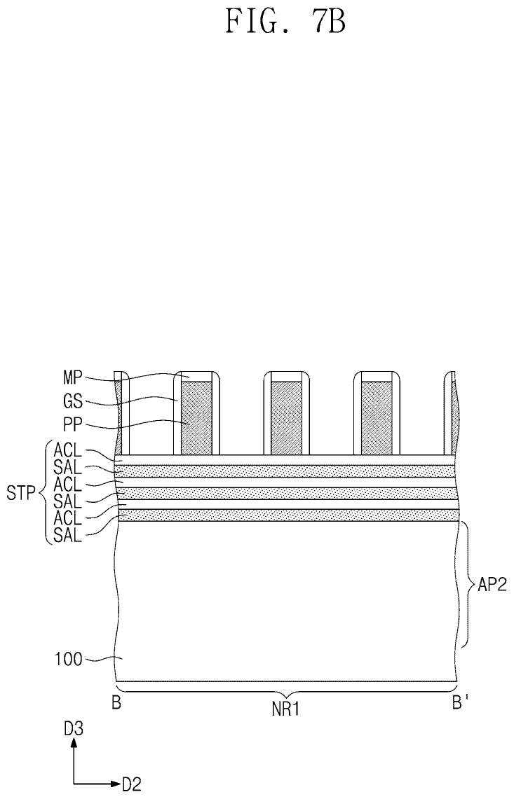

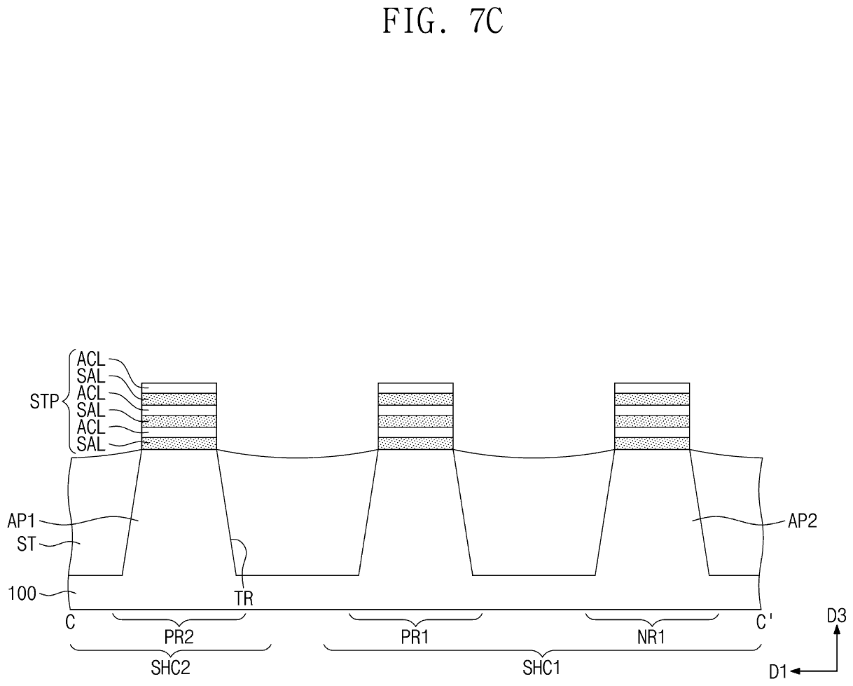

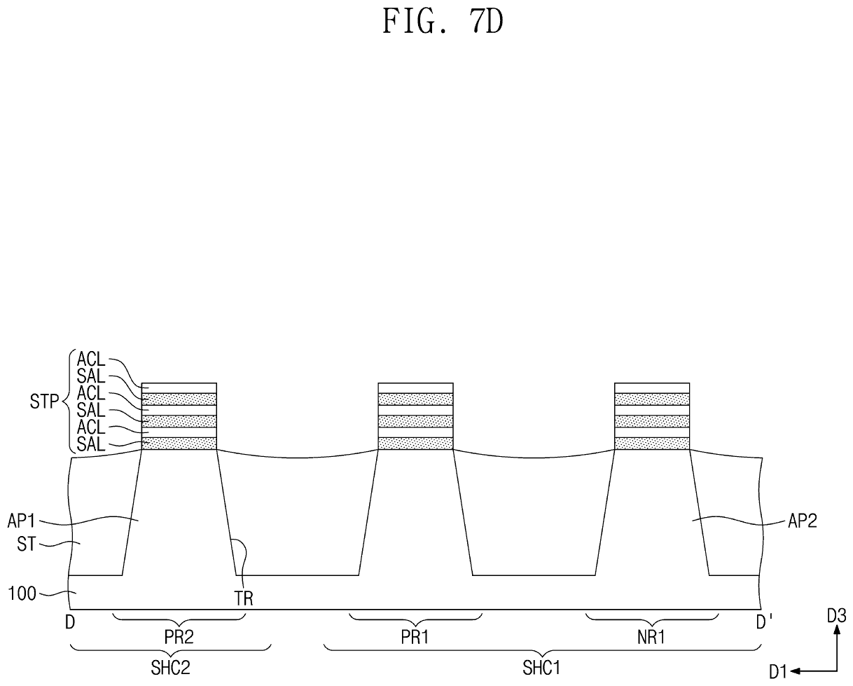

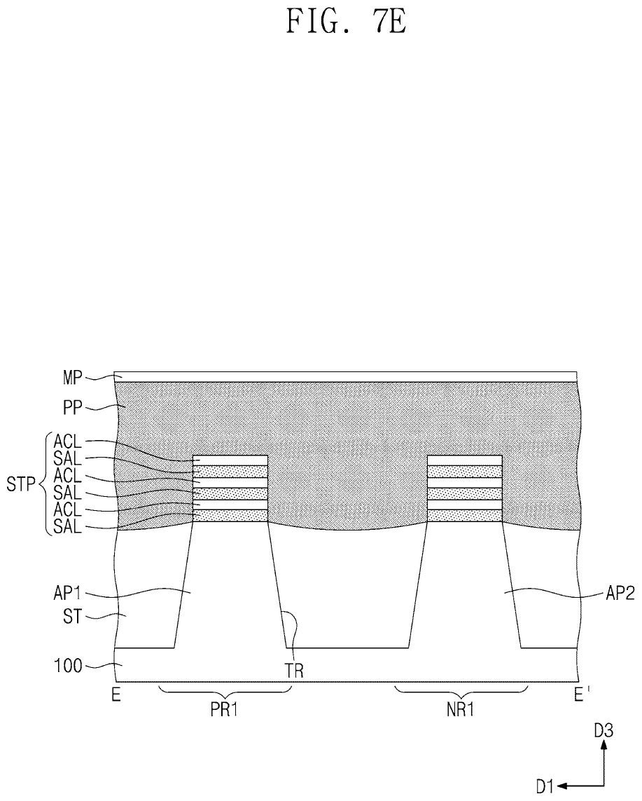

Referring to FIGS. 7A to 7E, sacrificial patterns PP may be formed on the substrate 100 to cross the stacking patterns STP. Each of the sacrificial patterns PP may be formed to have a line or a bar shape extending along the first direction D1.

In detail, the formation of the sacrificial patterns PP may include forming a sacrificial layer on the substrate 100, forming first hard mask patterns MP on the sacrificial layer, and patterning the sacrificial layer using the first hard mask patterns MP as an etch mask. The sacrificial layer may be formed of or include polysilicon, for example.

In some embodiments, a pair of gate spacers GS may be formed on opposite side surfaces of each of the sacrificial patterns PP. The formation of gate spacers GS may include conformally forming a gate spacer layer on the substrate 100 and anisotropically etching the gate spacer layer.

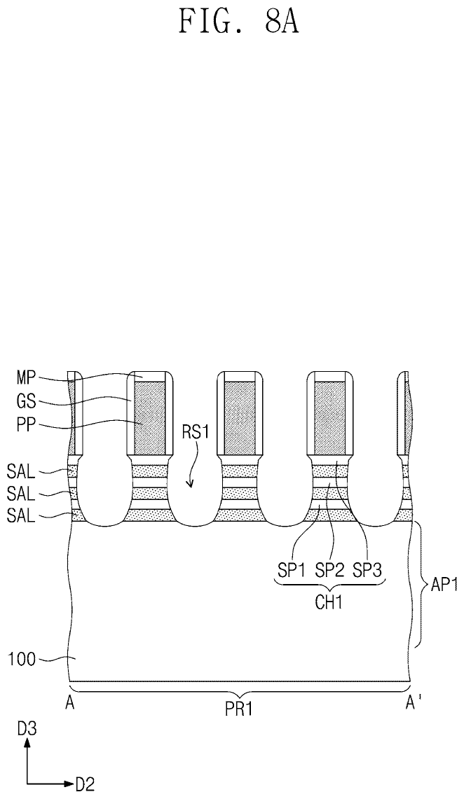

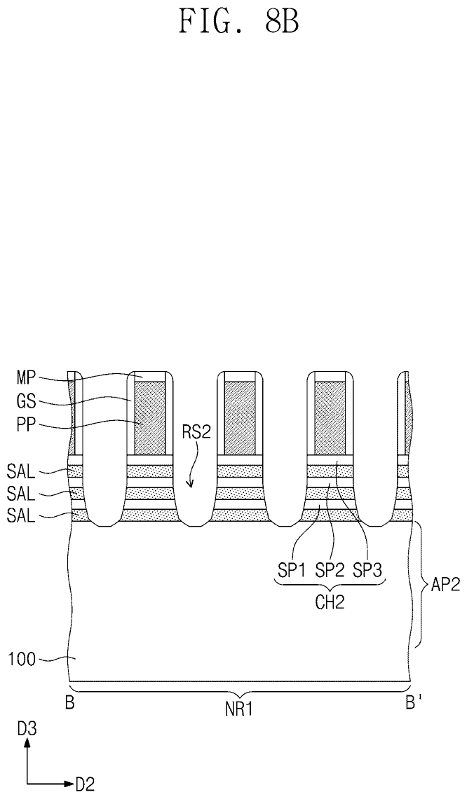

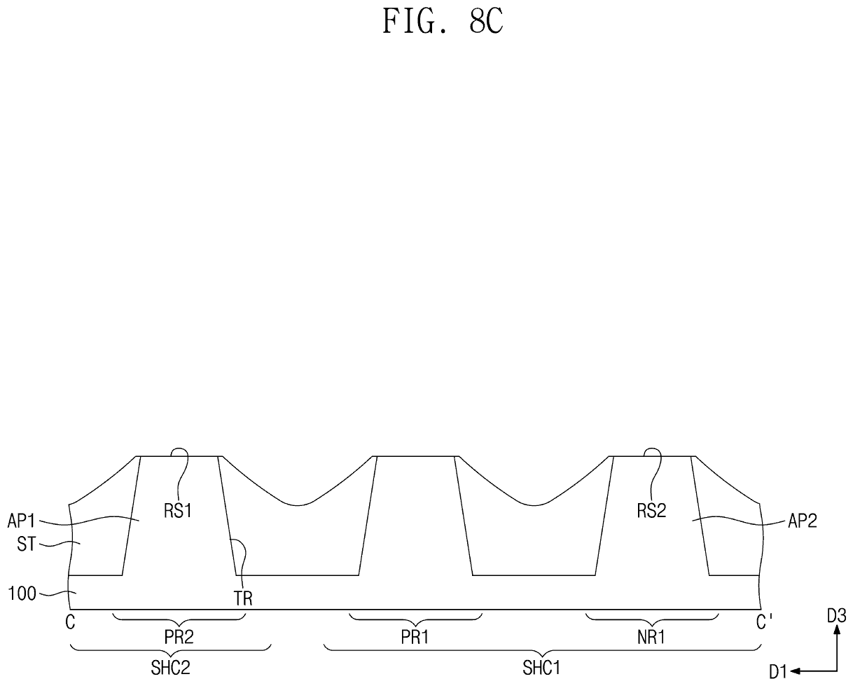

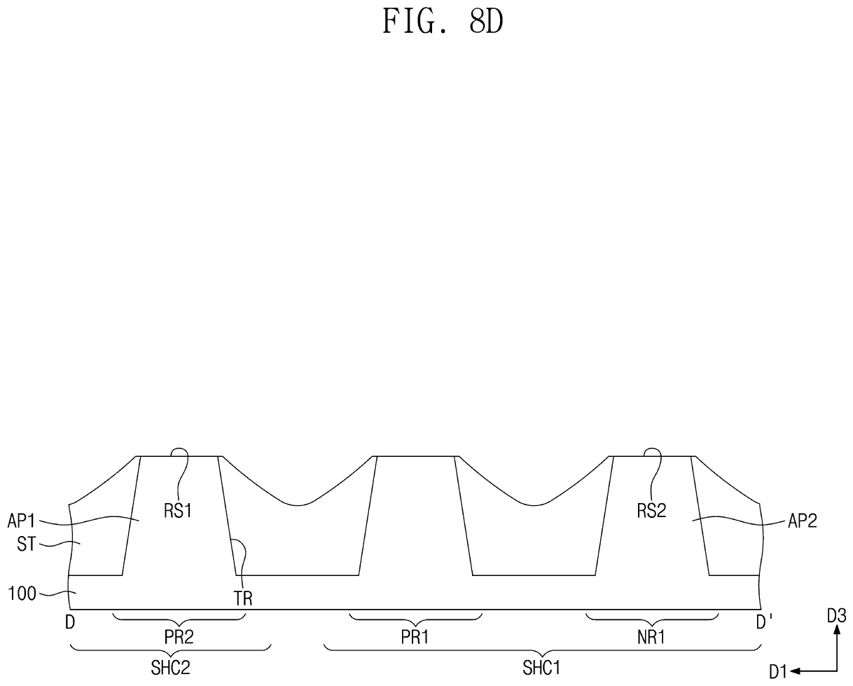

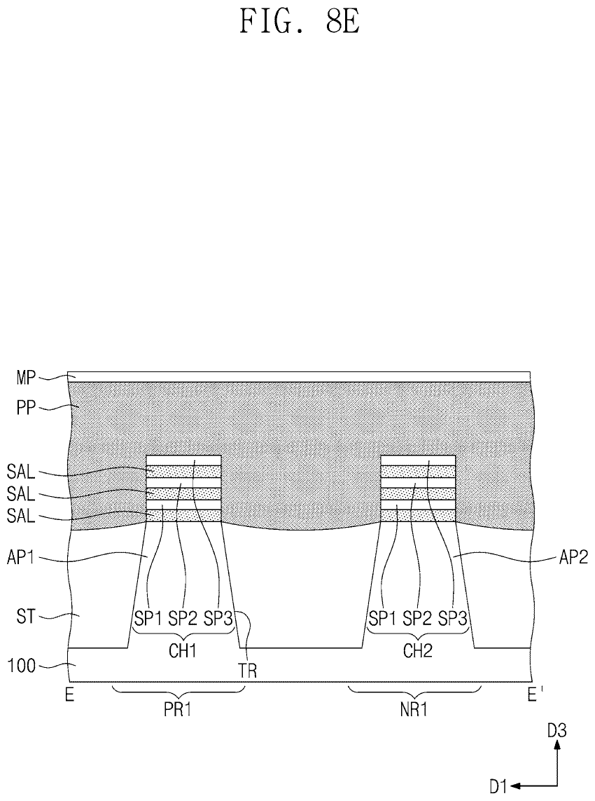

Referring to FIGS. 8A to 8D, first recess RS1 may be formed in the stacking pattern STP on the first active pattern AP1. Second recess RS2 may be formed in the stacking pattern STP on the second active pattern AP2. The device isolation layer ST on both sides of each of the first and second active patterns AP1 and AP2 may be further recessed during the formation of the first and second recesses RS1 and RS2.

In detail, the first recess RS1 may be formed by etching the stacking pattern STP on the first active pattern AP1 using the first hard mask patterns MP and the gate spacers GS as an etch mask. The first recess RS1 may be formed between a pair of the sacrificial patterns PP. The second recess RS2 in the stacking pattern STP on the second active pattern AP2 may be formed by the same method as that for the first recess RS1.

The first to third semiconductor patterns SP1, SP2, and SP3, which are sequentially stacked between adjacent ones of the first recess RS1, may be formed from the active layers ACL. The first to third semiconductor patterns SP1, SP2, and SP3, which are sequentially stacked between adjacent ones of the second recess RS2, may be formed from the active layers ACL. The first to third semiconductor patterns SP1, SP2, and SP3 between adjacent ones of the first recess RS1 may constitute the first channel pattern CH1. The first to third semiconductor patterns SP1, SP2, and SP3 between the adjacent ones of the second recess RS2 may constitute the second channel pattern CH2.

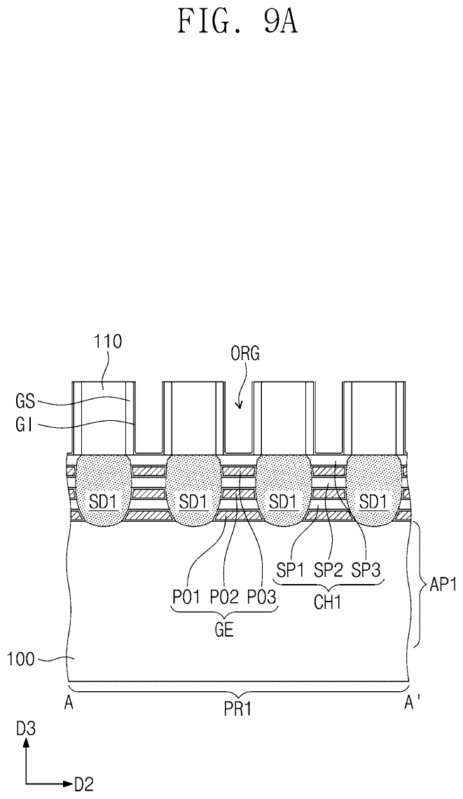

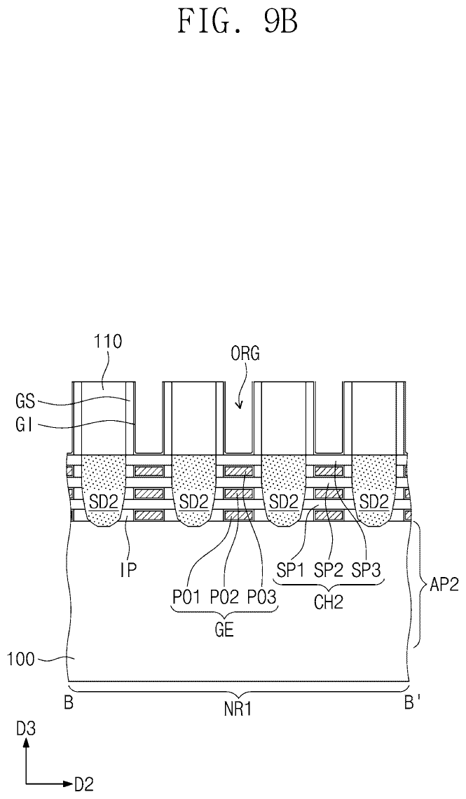

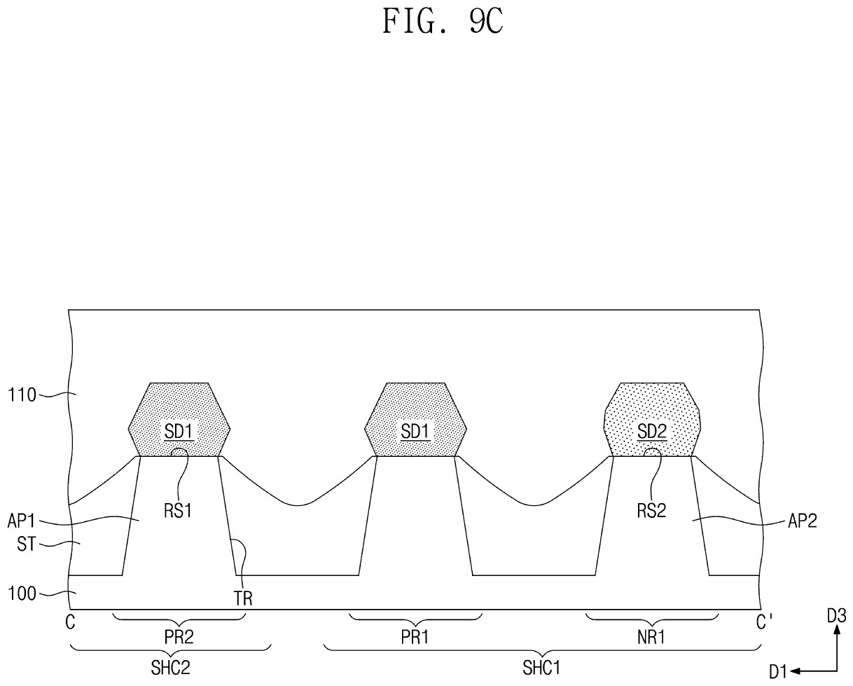

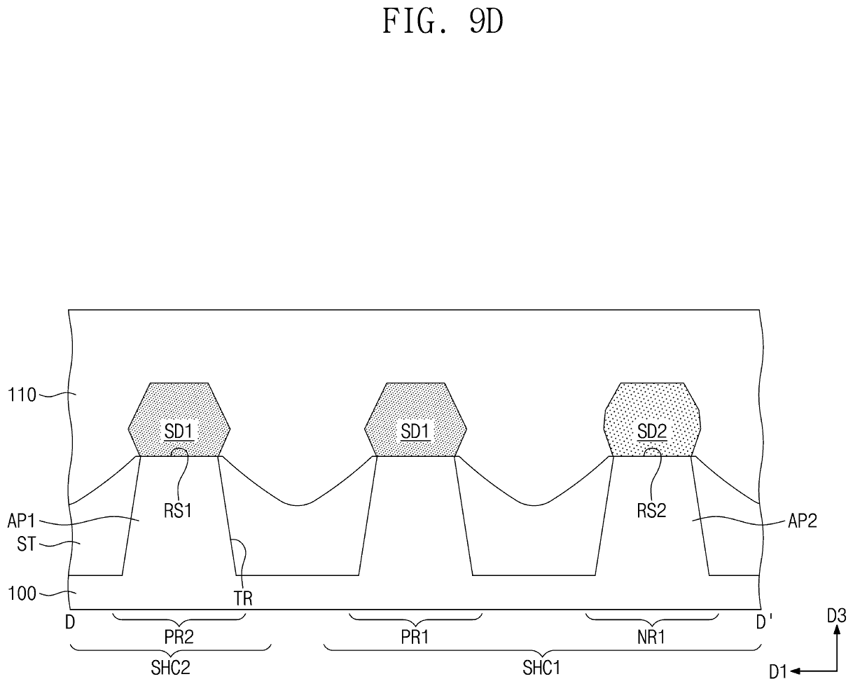

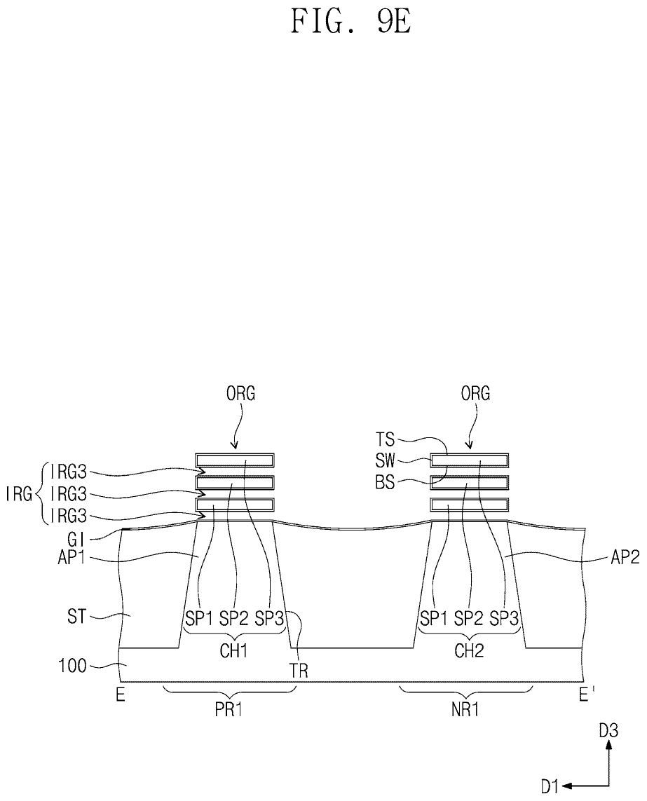

Referring to FIGS. 9A to 9E, the first source/drain patterns SD1 may be formed in the first recess RS1, respectively. In detail, the first source/drain pattern SD1 may be formed by performing a first selective epitaxial growth (SEG) process using an inner surface of the first recess RS1 as a seed layer. The first SEG process may include a chemical vapor deposition (CVD) process or a molecular beam epitaxy (MBE) process.

The first source/drain pattern SD1 may be formed of or include a semiconductor material (e.g., SiGe) having a lattice constant larger than that of the substrate 100. During the first SEG process, impurities may be injected in an in-situ manner. In some embodiments, impurities may be injected into the first source/drain pattern SD1, after the formation of the first source/drain pattern SD1. The first source/drain pattern SD1 may be doped to have a first conductivity type (e.g., p-type).

The second source/drain patterns SD2 may be formed in the second recesses RS2, respectively. In detail, the second source/drain pattern SD2 may be formed by performing a second SEG process using an inner surface of the second recess RS2 as a seed layer. In some embodiments, the second source/drain pattern SD2 may include the same semiconductor material (e.g., Si) as the substrate 100. The second source/drain pattern SD2 may be doped to have a second conductivity type (e.g., n-type). Inner spacers IP may be respectively formed between the second source/drain pattern SD2 and the first sacrificial layers SAL.

The first interlayer insulating layer 110 may cover the first and second source/drain patterns SD1 and SD2, the first hard mask patterns MP, and the gate spacers GS. The first interlayer insulating layer 110 may be planarized until top surfaces of the sacrificial patterns PP are exposed. The planarization of the first interlayer insulating layer 110 may be performed using an etch-back process or a chemical-mechanical polishing (CMP) process. In some embodiments, the first hard mask patterns MP may be fully removed during the planarization process.

The sacrificial patterns PP exposed may be selectively removed. As a result of the removal of the sacrificial patterns PP, an outer region ORG may be formed to expose the first and second channel patterns CH1 and CH2. The removal of the sacrificial patterns PP may include a wet etching process which is performed using an etching solution capable of selectively etching polysilicon.

Inner regions IRG may be formed by selectively removing the first sacrificial layers SAL exposed through the outer region ORG. For example, a selective etching process may be performed to selectively remove the first sacrificial layers SAL and to leave the first to third semiconductor patterns SP1, SP2, and SP3. An etch recipe for the etching process may be chosen to etch a layer (e.g., a silicon germanium layer), which is formed to have a relatively high germanium concentration, at a high etch rate.

The first sacrificial layers SAL on the first and second active patterns AP1 and AP2 may be removed during the etching process. The etching process may be a wet etching process. An etchant material, which is used in the etching process, may be chosen to quickly remove the first sacrificial layers SAL having a relatively high germanium concentration.

Since the first sacrificial layers SAL are selectively removed, only the stack of the first to third semiconductor patterns SP1, SP2, and SP3 may be left on each of the first and second active patterns AP1 and AP2. Empty regions, which are formed by removing the first sacrificial layers SAL, may form the first to third inner regions IRG1, IRG2, and IRG3, respectively.

The gate insulating layer GI may be formed on the first to third semiconductor patterns SP1, SP2, and SP3 exposed. The gate insulating layer GI may be formed to enclose each of the first to third semiconductor patterns SP1, SP2, and SP3.

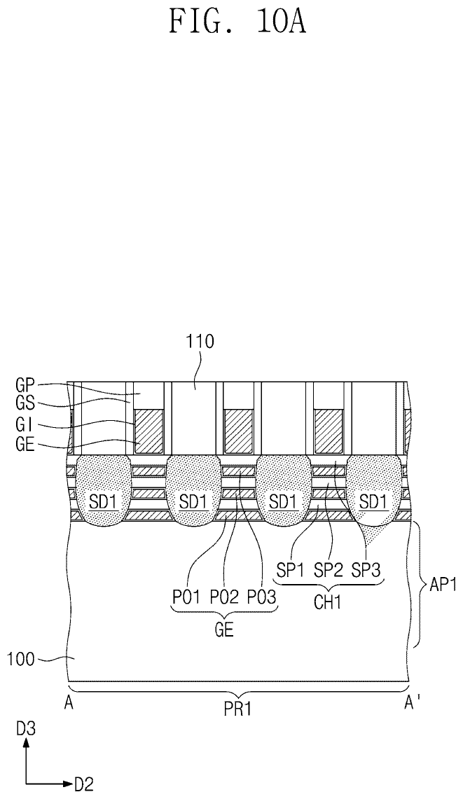

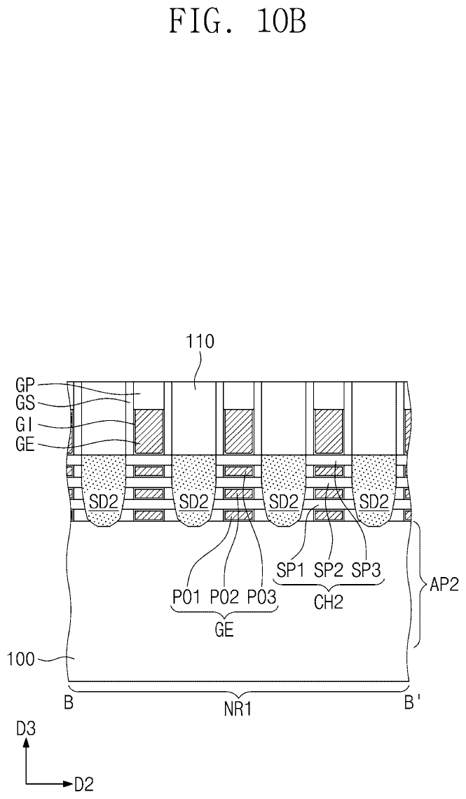

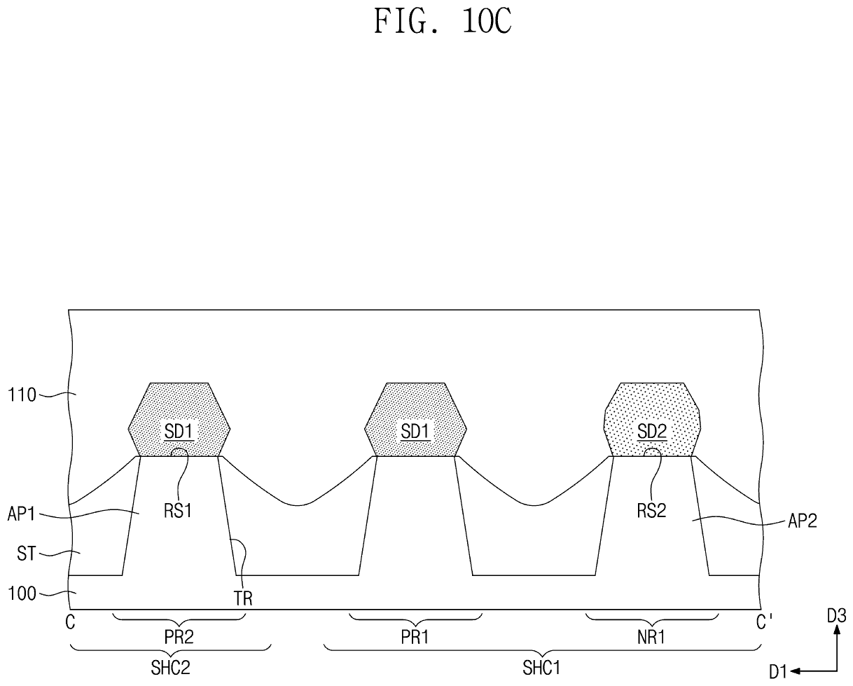

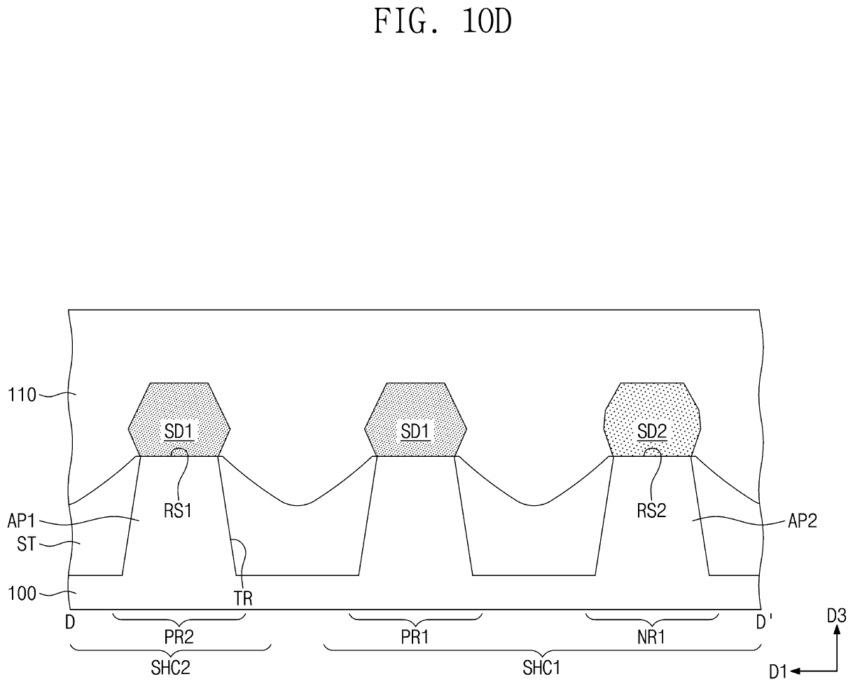

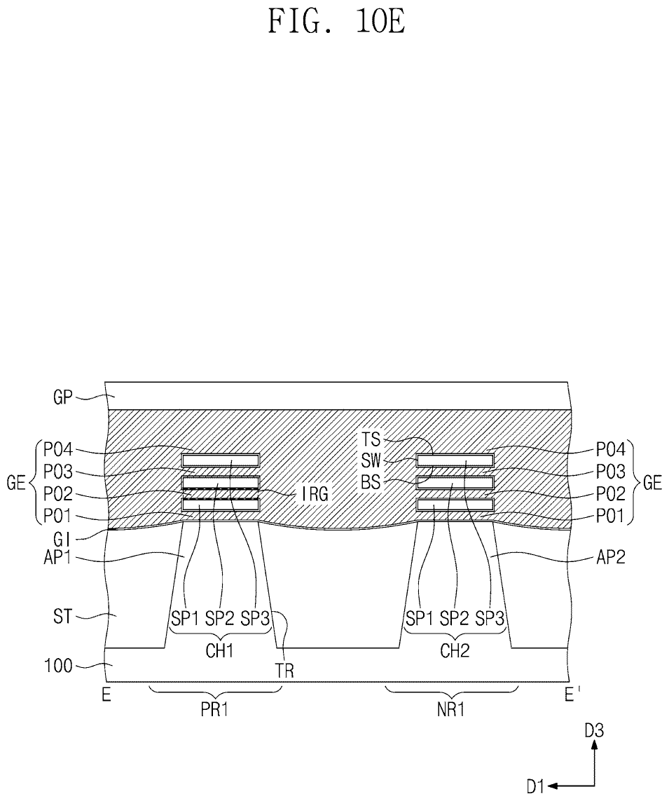

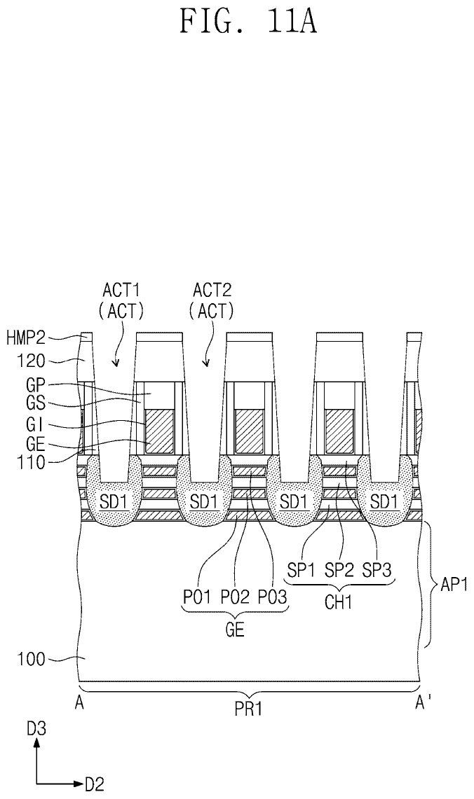

Referring to FIGS. 10A to 10E, the gate electrode GE may include the first to third portions PO1, PO2, and PO3, which are formed in the first to third inner regions IRG1, IRG2, and IRG3, respectively, and the fourth portion PO4, which is formed in the outer region ORG. The gate electrode GE may be recessed to have a reduced height. The gate capping pattern GP may be formed on the recessed gate electrode GE.

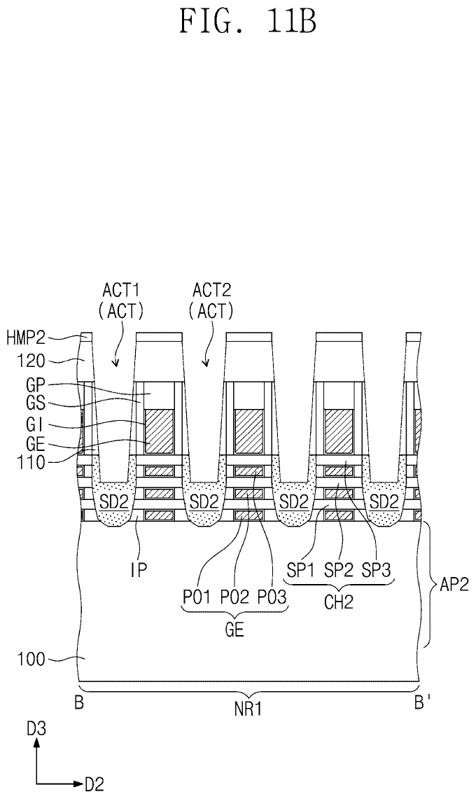

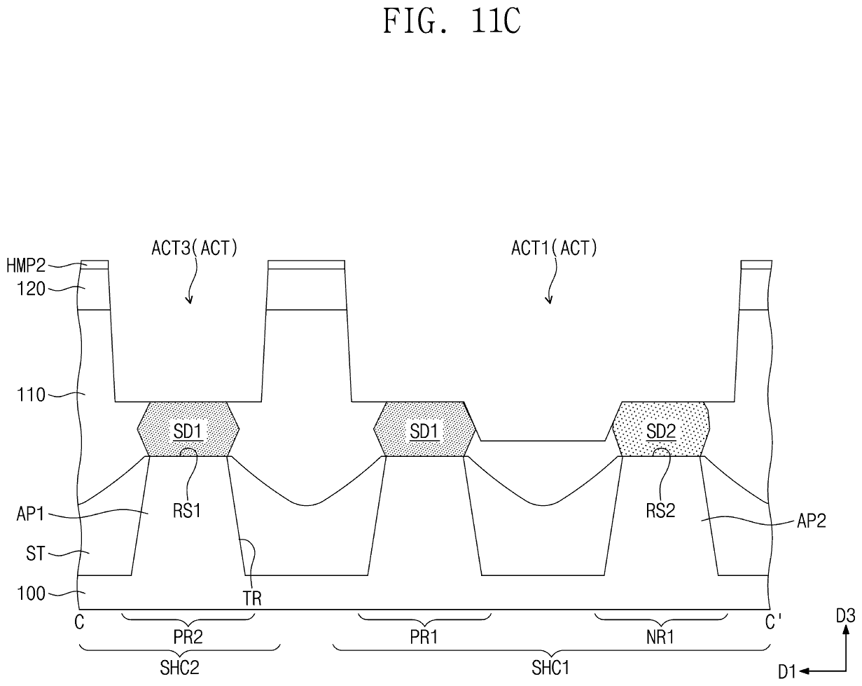

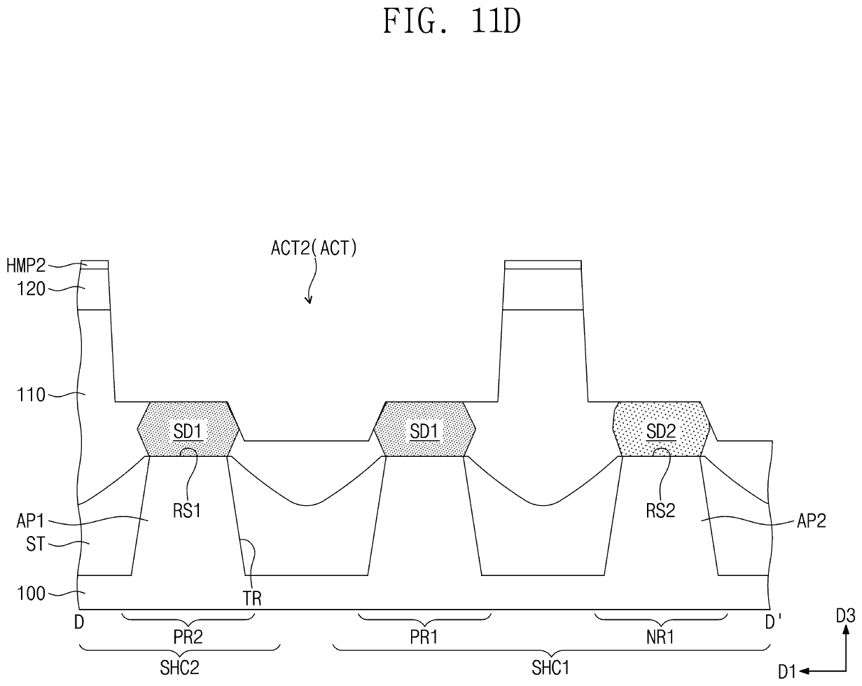

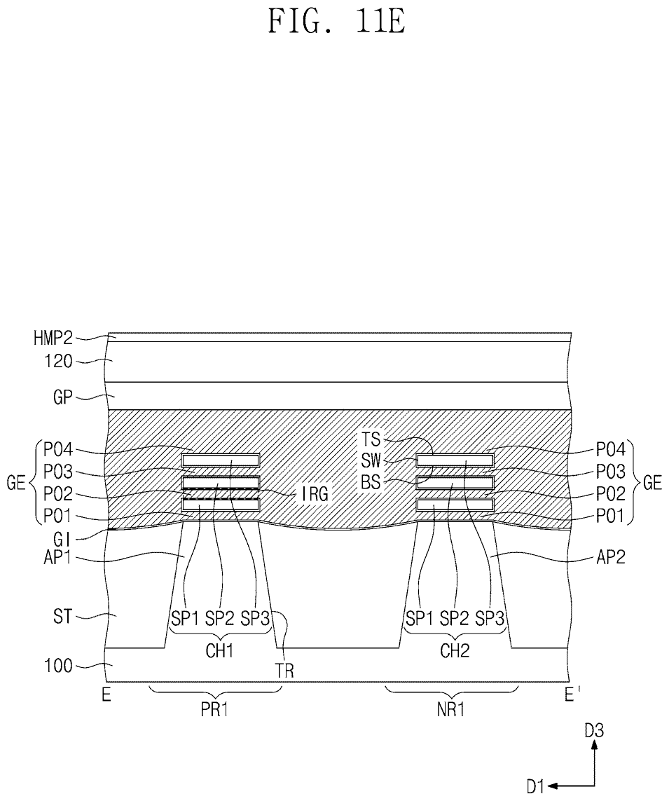

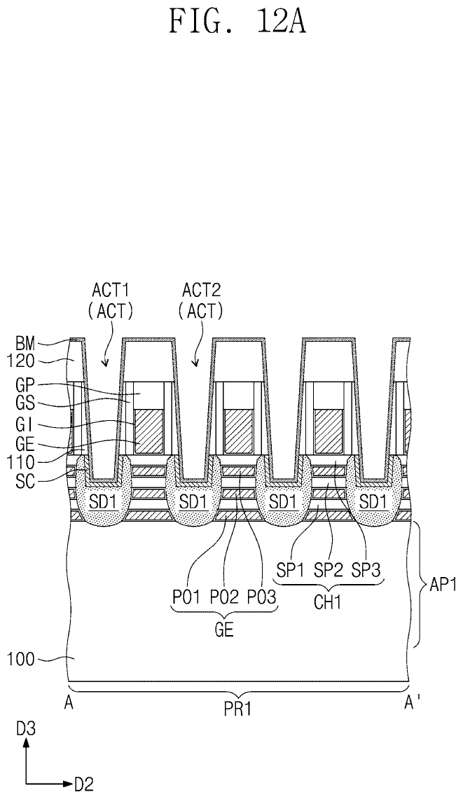

Referring to FIGS. 11A to 11E, the second interlayer insulating layer 120 may be formed on the first interlayer insulating layer 110. The second interlayer insulating layer 120 may be formed on the gate spacer GS and the gate capping pattern GP.

Active contact trenches ACT may be formed to penetrate the second and first interlayer insulating layers 120 and 110, respectively. The active contact trenches ACT may include a first active contact trench ACT1, a second active contact trench ACT2, and a third active contact trench ACT3.

In some embodiments, the formation of the active contact trenches ACT may include forming a second hard mask pattern HMP2 on the second interlayer insulating layer 120 and etching the second and first interlayer insulating layers 120 and 110, respectively, using the second hard mask pattern HMP2 as an etch mask.

The etching process may be performed to remove an upper portion of each of the first and second source/drain patterns SD1 and SD2.

To do this, the etching process may be performed in an over-etching manner. In this case, the first interlayer insulating layer 110 between the first and second source/drain patterns SD1 and SD2 may be recessed to have the bottommost surfaces that are located at a level lower than top surfaces of the first and second source/drain patterns SD1 and SD2, as shown in FIG. 11C. Similarly, the first interlayer insulating layer 110 between the first source/drain pattern SD1 of the first PMOSFET region PR1 and the first source/drain pattern SD1 of the second PMOSFET region PR2 may be recessed to have the bottommost surfaces that are located at a level lower than the top surface of each of the first source/drain patterns SD1, as shown in FIG. 11D. The second hard mask pattern HMP2 may be removed, after the formation of the active contact trenches ACT.

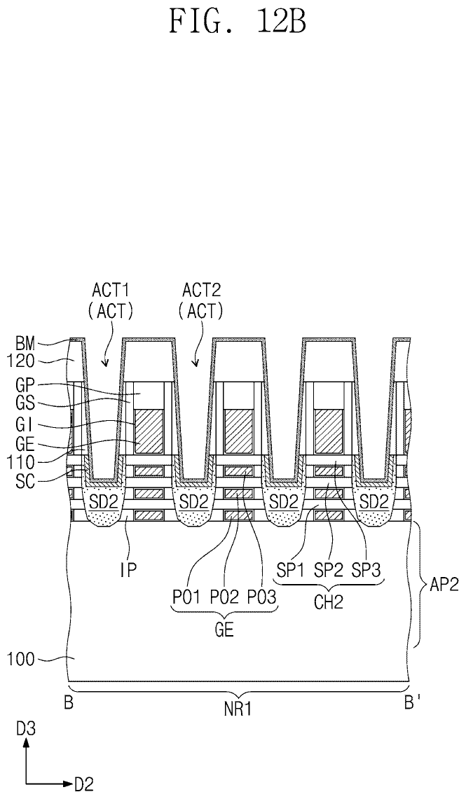

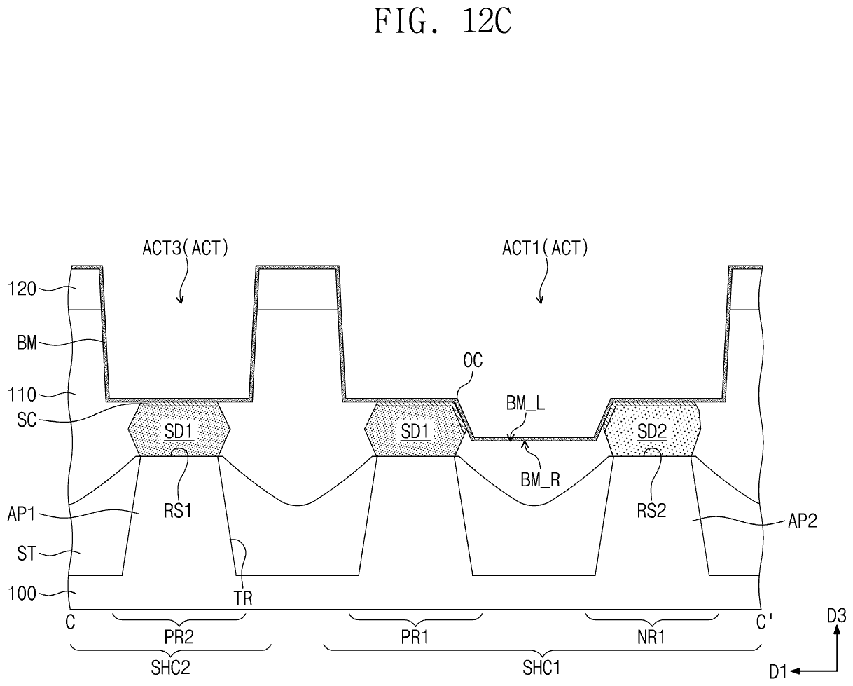

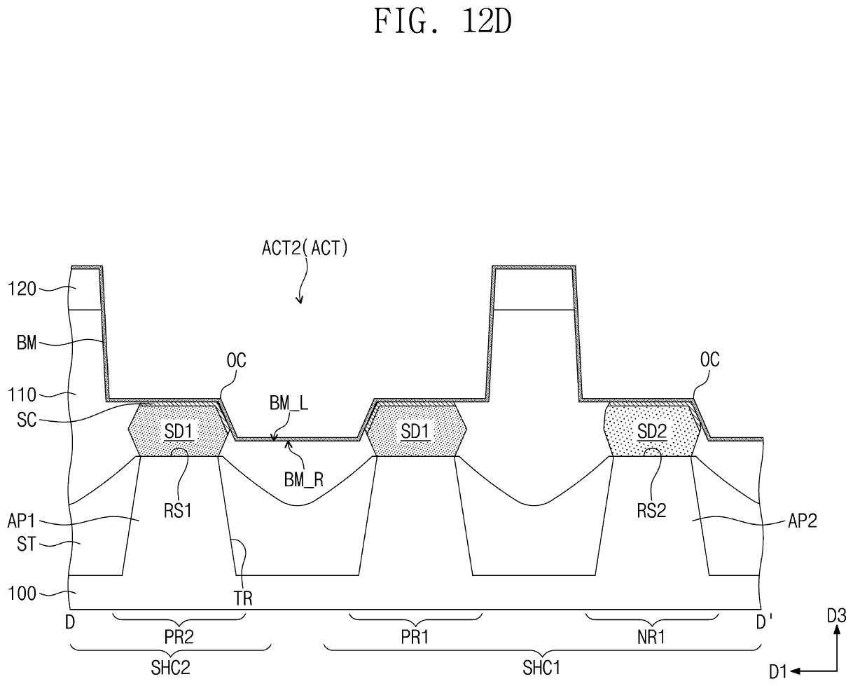

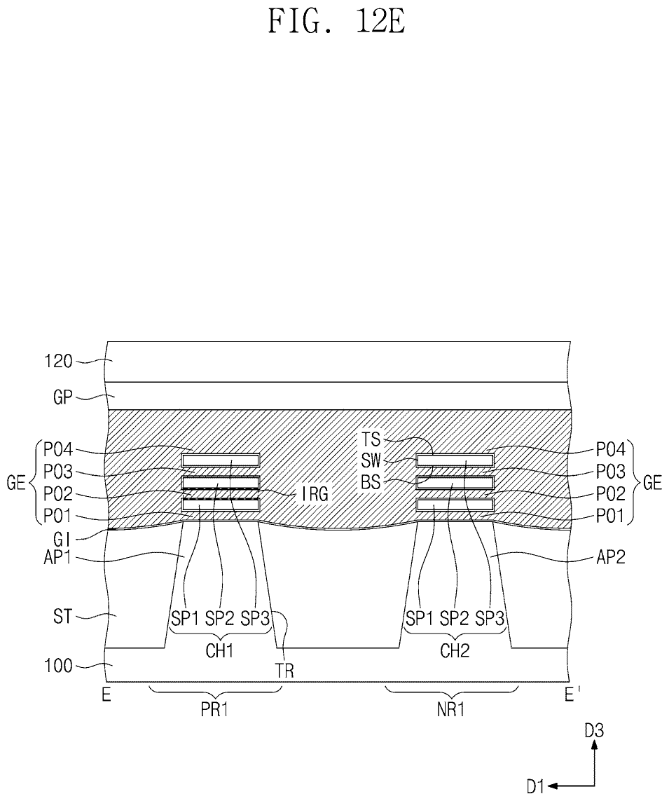

Referring to FIGS. 12A to 12E, the barrier pattern BM may be formed in the active contact trenches ACT. The barrier pattern BM may be provided to cover a top surface of the second interlayer insulating layer 120 and may be extended alongside and bottom surfaces of the active contact trenches ACT. The silicide pattern SC may be formed between the first source/drain pattern SD1 and the barrier pattern BM and between the second source/drain pattern SD2 and the barrier pattern BM.

Referring to FIG. 12C, the barrier pattern BM may be extended along the first interlayer insulating layer 110 recessed by the over-etching process. That is, the barrier pattern BM may have the recess region BM_R, which is formed in the first active contact trench ACT1 and between the first and second source/drain patterns SD1 and SD2 and is recessed toward the device isolation layer ST. The recess region BM_R of the barrier pattern BM may be formed at a level, which is different from the barrier pattern BM on the top surfaces of the source/drain patterns SD1 and SD2, thereby forming a stepwise structure in the third direction D3. The barrier pattern BM may have a corner portion OC. The corner portion OC may refer to a bent portion, which is defined by the barrier pattern BM on the source/drain pattern and the barrier pattern BM on the recess region BM_R.

Similarly, referring to FIG. 12D, the barrier pattern BM may have the recess region BM_R, which is located in the second active contact trench ACT2 and between the first source/drain patterns SD1 of the first and second PMOSFET regions PR1 and PR2 and is recessed toward the device isolation layer ST. The barrier pattern BM may have the corner portion OC. The corner portion OC may refer to a bent portion, which is defined by the barrier pattern BM on the source/drain patterns SD1 and the barrier pattern BM on the recess region BM_R.

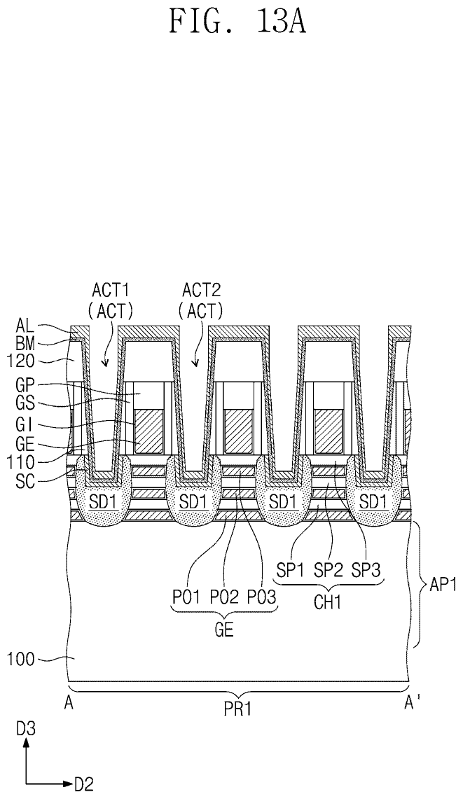

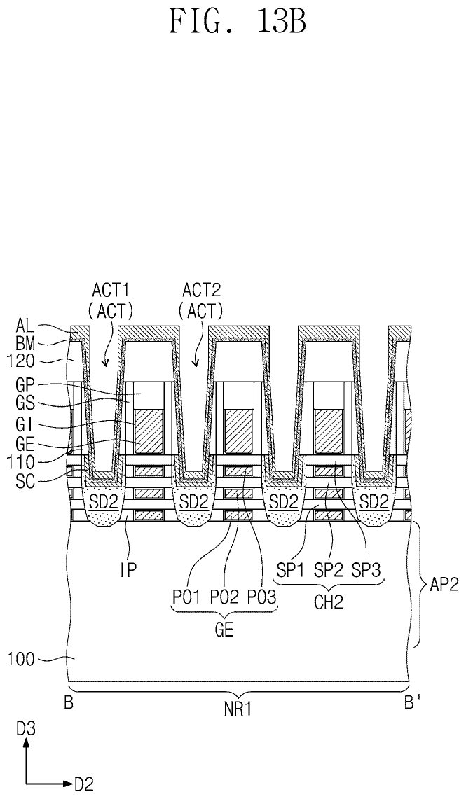

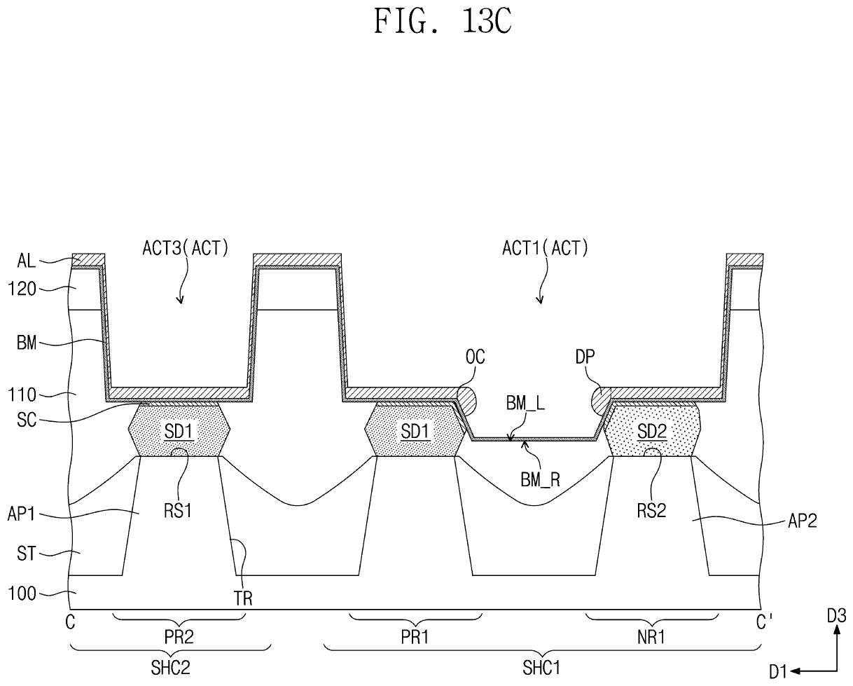

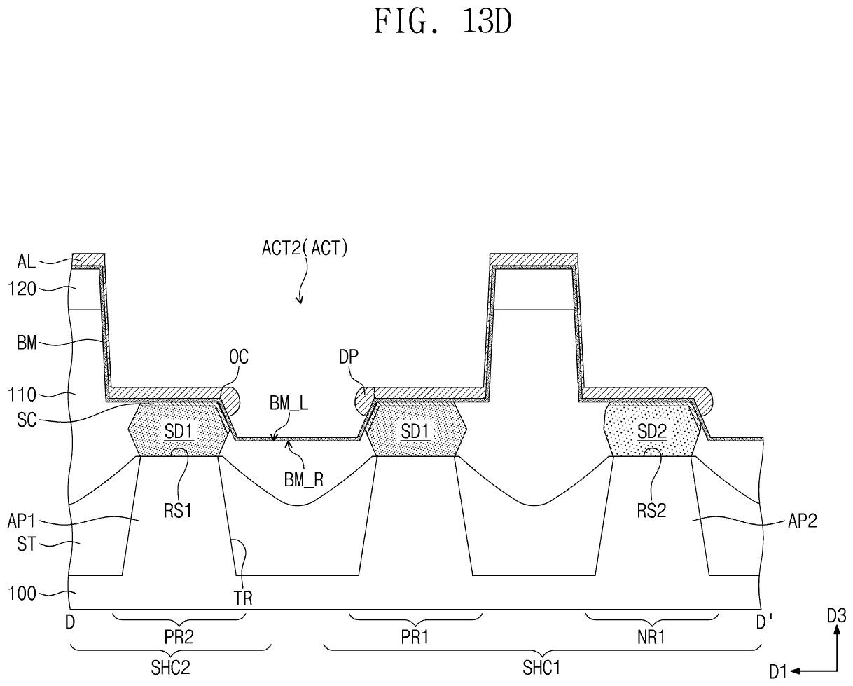

Referring to FIGS. 13A to 13D, the active contact liner AL may be formed on the barrier pattern BM and may be extended to the side and bottom surfaces of the active contact trenches ACT. In some embodiments, the formation of the active contact liner AL may include depositing a metallic material in the active contact trench ACT through a physical vapor deposition (PVD) process. The PVD process may be, for example, a plasma-using sputtering process performed under the condition of low substrate bias. In some embodiments, the substrate bias may range from 150 Wb to 50 Wb or from 100 Wb to 10 Wb. The Wb refers to magnetic flux. The active contact liner AL may be formed of or include at least one of metallic materials (e.g., aluminum, copper, tungsten, molybdenum, and cobalt).

Referring to FIG. 13C, the active contact liner AL may be formed in the first active contact trench ACT1 and on the top surfaces of the first and second source/drain patterns SD1 and SD2. The active contact liner AL may have a protruding portion DP, which is formed near the corner portion OC and protrudes in the first direction D1. The protruding portion DP may be formed by the PVD process being performed under a low bias condition. The protruding portion DP may be formed by the metal material may be over deposited (for example, overhang) on the corner portion OC. Furthermore, in the case where the PVD process is performed under the low bias condition, the active contact liner AL may not be formed on the recess region BM_R of the barrier pattern BM, and thus, the bottommost surface BM_L of the barrier pattern BM may be exposed to the first active contact trench ACT1.

Similarly, referring to FIG. 13D, the active contact liner AL may be formed in the second active contact trench ACT2 and on the first source/drain patterns SD1 of the first and second PMOSFET regions PR1 and PR2. The active contact liner AL may not be formed on the recess region BM_R of the barrier pattern BM, and thus, the bottommost surface BM_L of the barrier pattern BM may be exposed to the second active contact trench ACT2. The active contact liner AL may protrude in the first direction D1, near the corner portions OC. This may result from the over deposition (for example, overhang) of the metal material, which occurs at the corner portion OC when the PVD process is performed under the low bias condition.

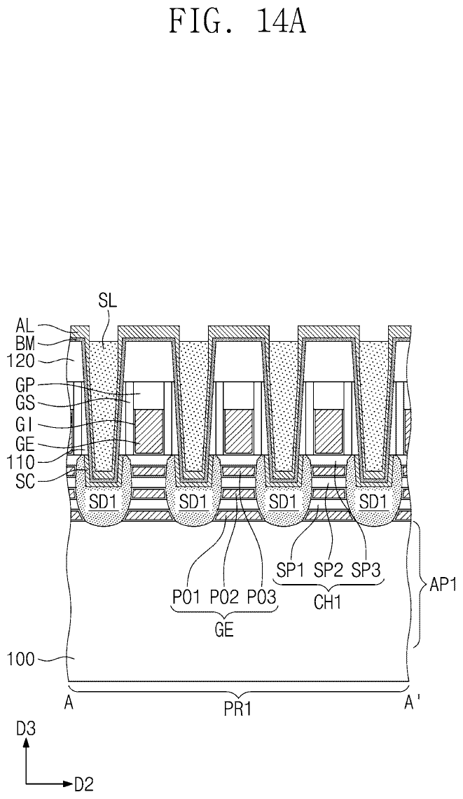

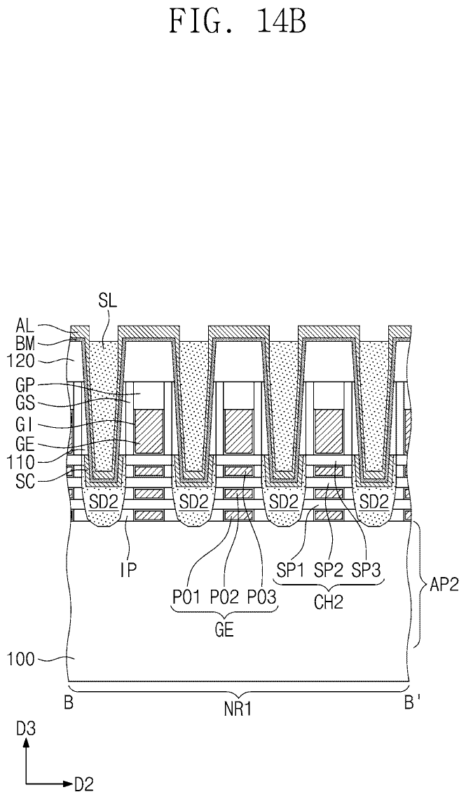

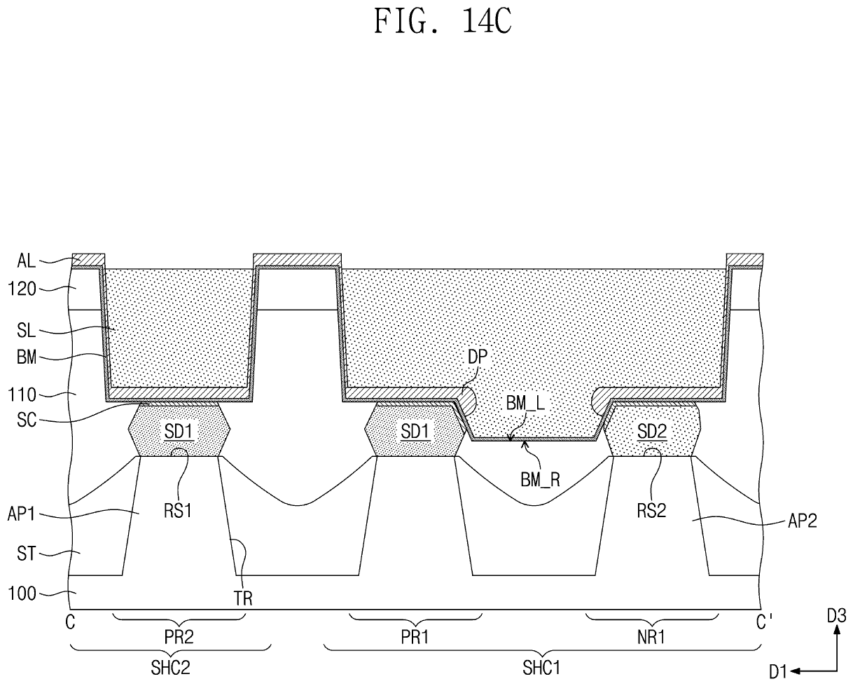

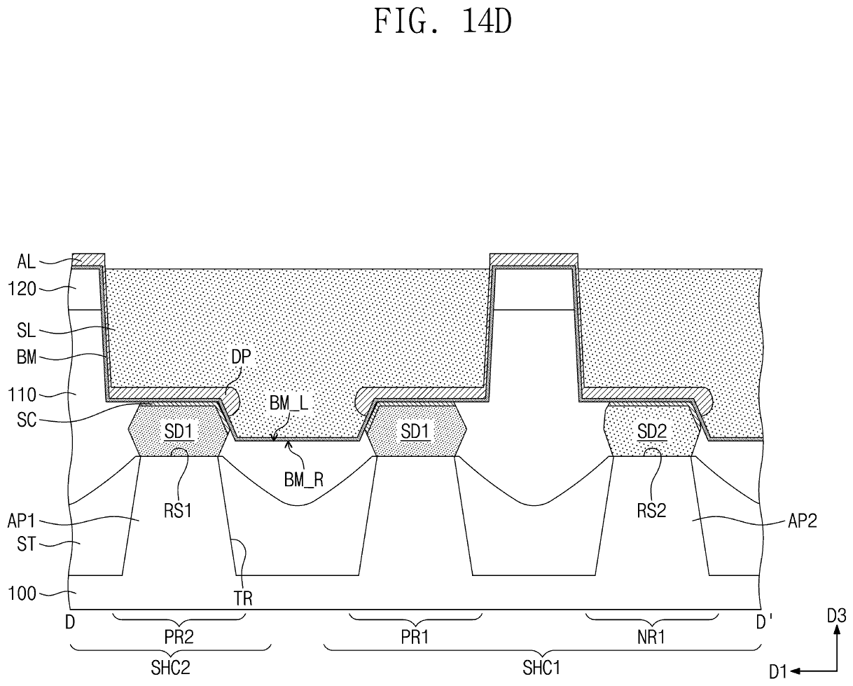

Referring to FIGS. 14A to 14D, a second sacrificial layer SL may be formed to fill the active contact trench ACT. The second sacrificial layer SL may cover the active contact liner AL in the active contact trench ACT and may cover the protruding portion DP. The second sacrificial layer SL may fill the recess region BM_R of the barrier pattern BM and the exposed bottommost surface BM_L of the barrier pattern BM. In some embodiments, the second sacrificial layer SL may be formed of or include silicon oxide.

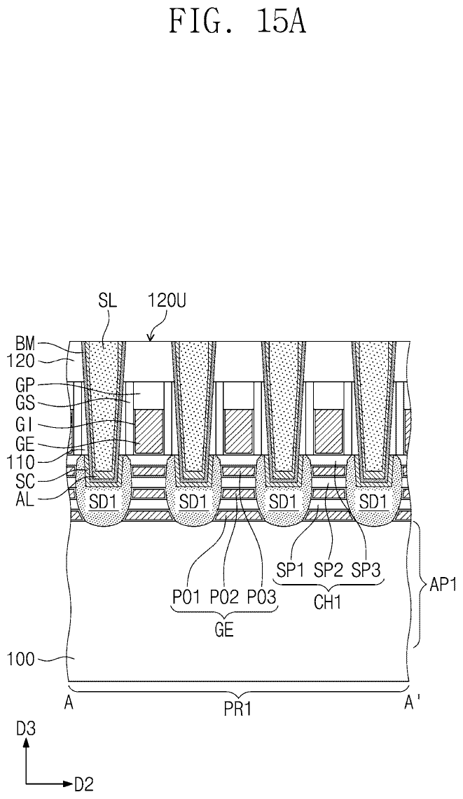

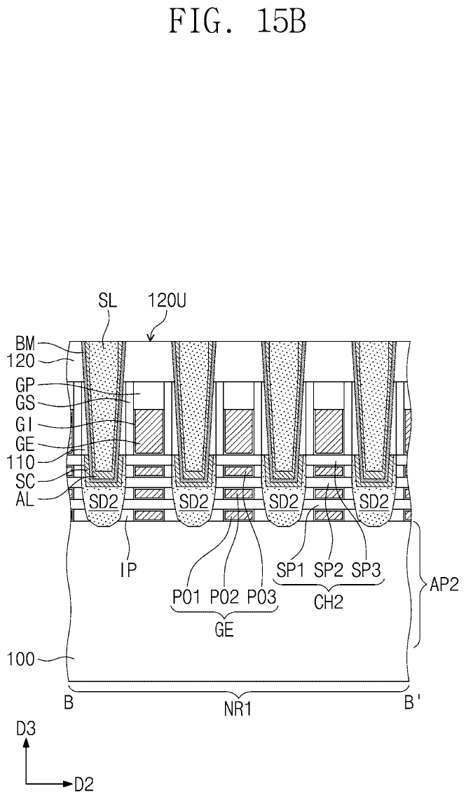

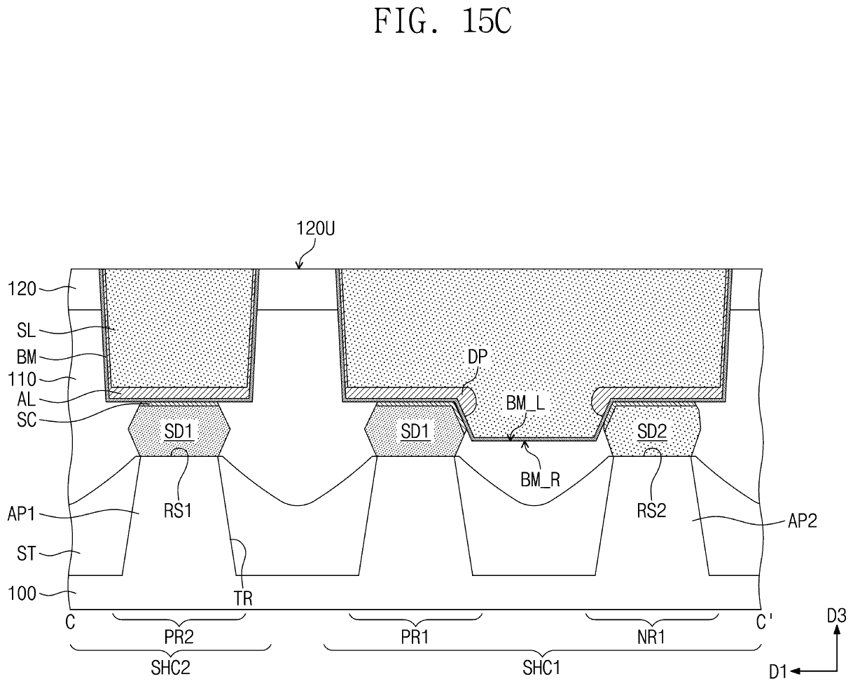

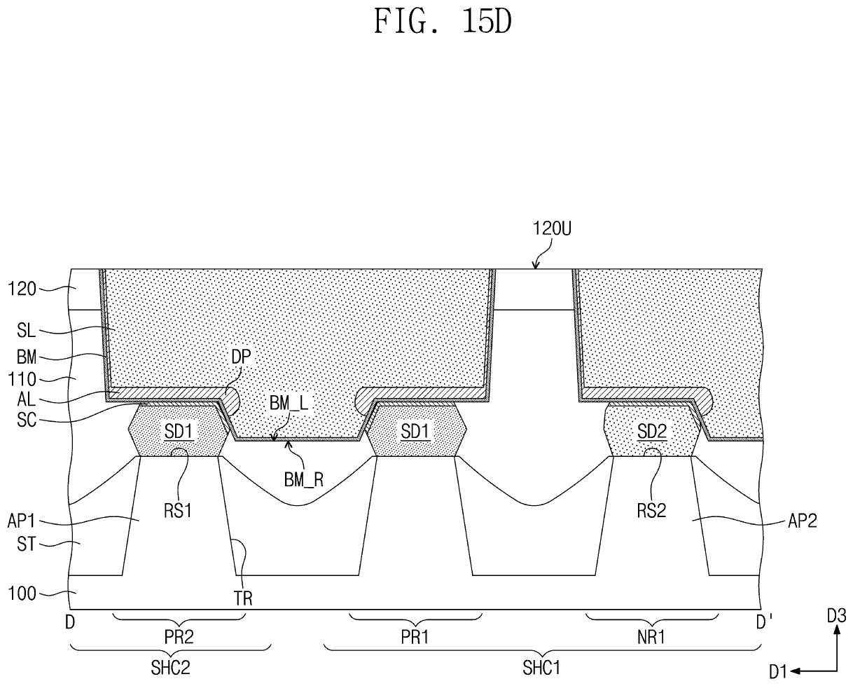

Referring to FIGS. 15A to 15D, the barrier pattern BM and the active contact liner AL on the second interlayer insulating layer 120 may be removed. In some embodiments, the barrier pattern BM and the active contact liner AL may be removed through a wet etching process. As a result of the wet etching process, a top surface 120U of the second interlayer insulating layer 120 may be exposed.

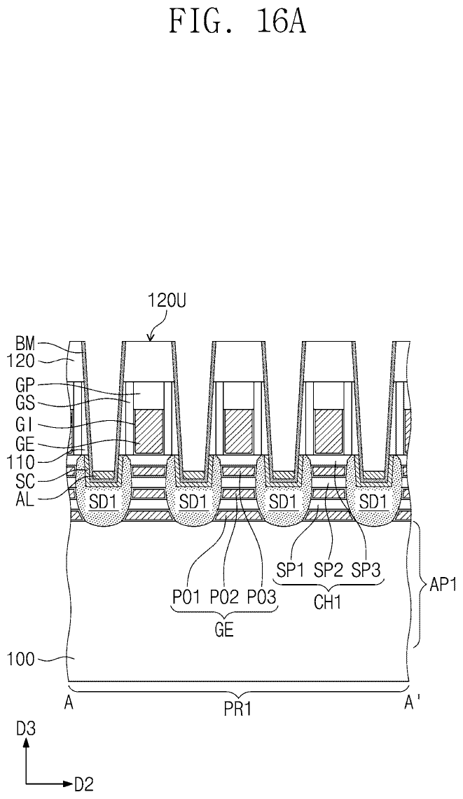

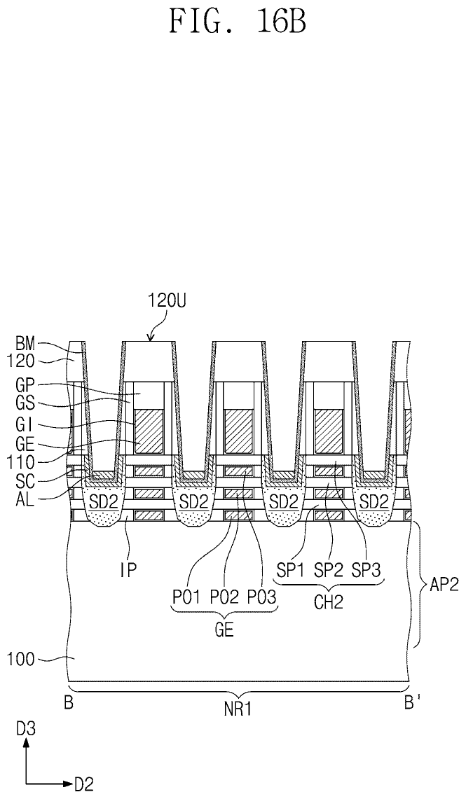

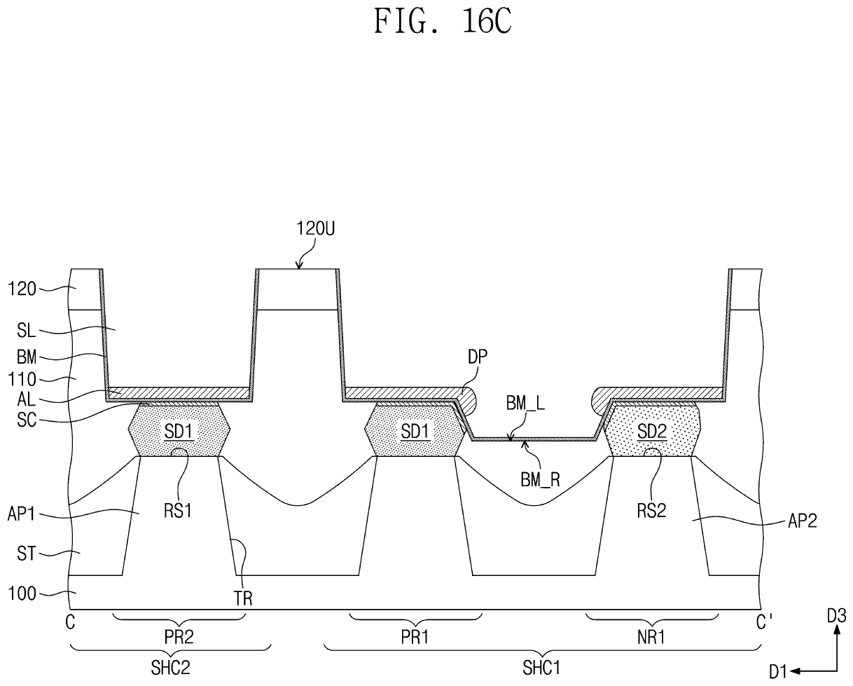

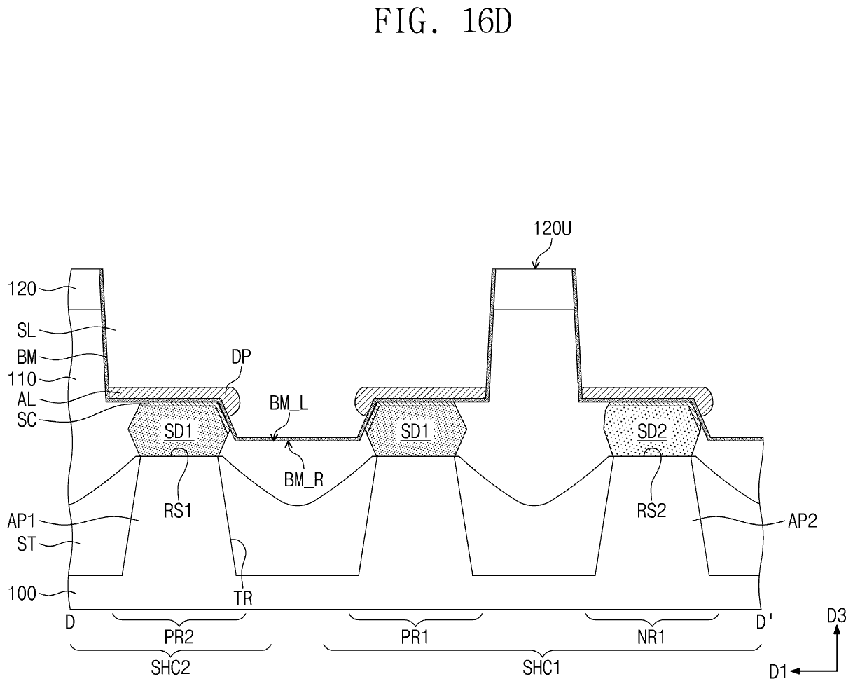

Referring to FIGS. 16A to 16D, the second sacrificial layer SL may be removed. In some embodiments, the removal of the second sacrificial layer SL may be performed using an ashing process. The active contact liner AL, which is extended in the side surface of the active contact trench ACT, may be removed by the ashing process. Furthermore, the ashing process may be performed to expose the recess region BM_R of the barrier pattern BM and expose the bottommost surface BM_L of the barrier pattern BM. The protruding portion DP of the active contact liner AL may be exposed.

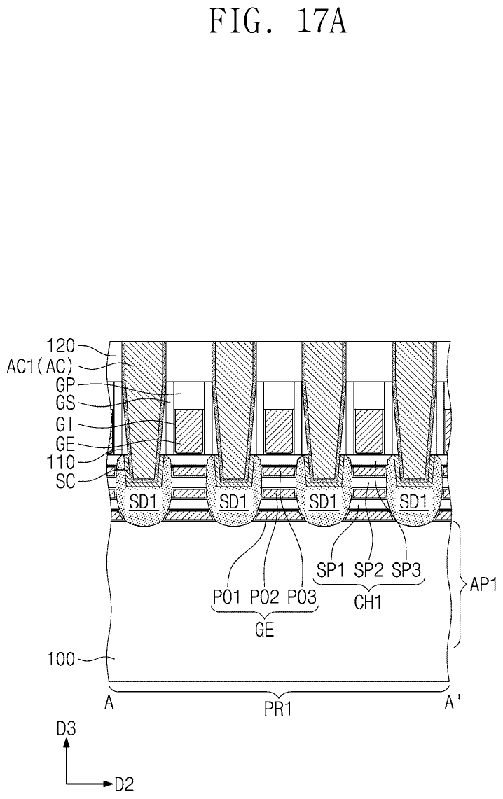

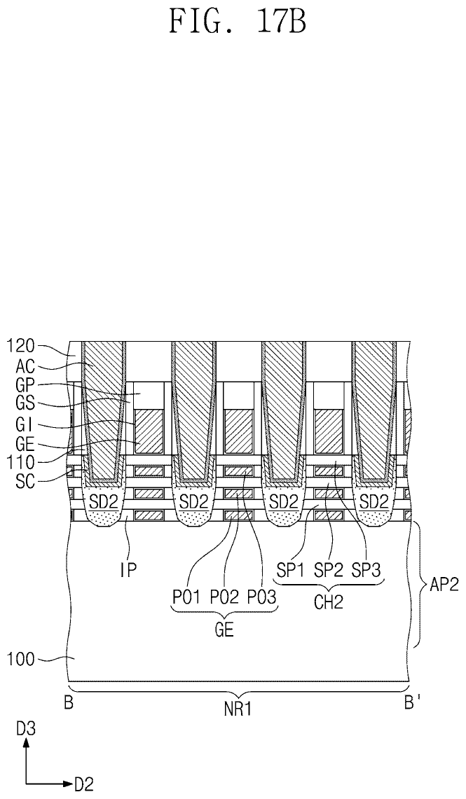

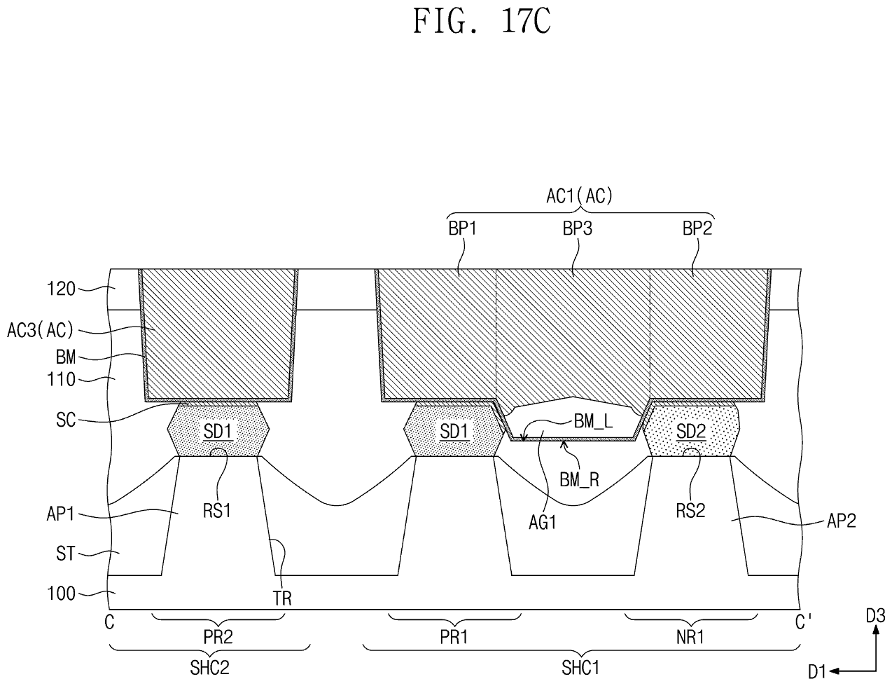

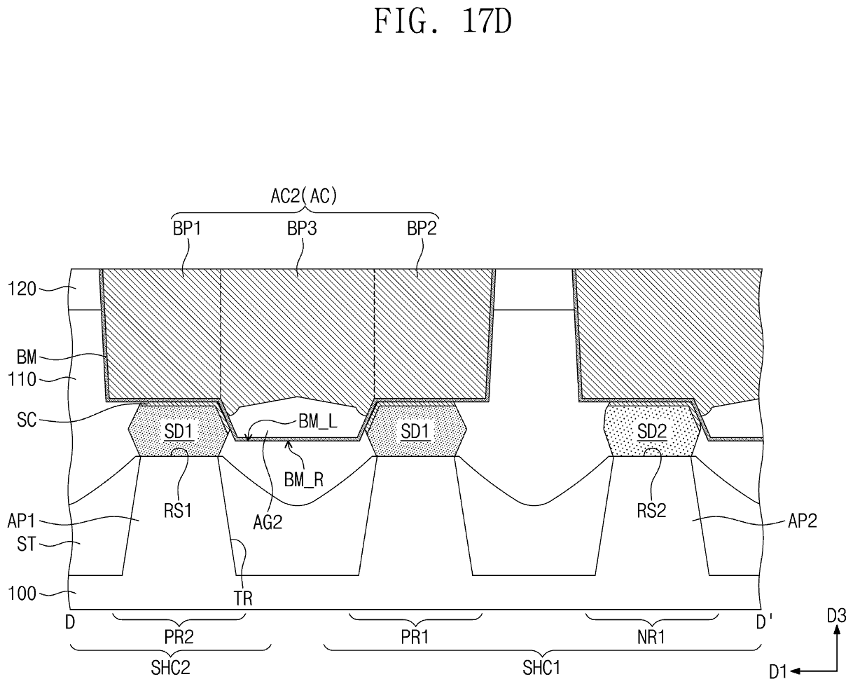

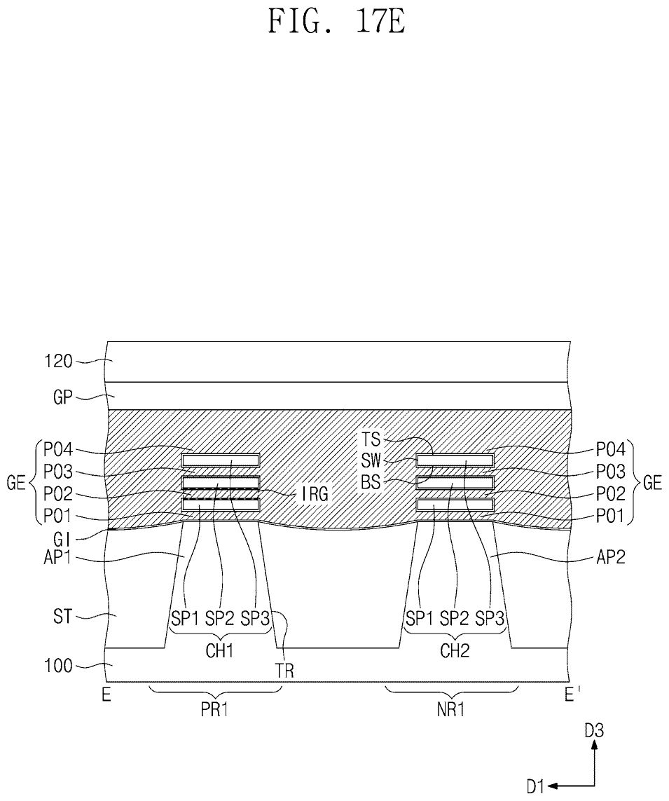

Referring to FIGS. 17A to 17E, the active contacts AC may be formed to fill the active contact trench ACT. In detail, the first, second, and third active contacts AC1, AC2, and AC3 may be formed to fill the first to third active contact trenches ACT1, ACT2, and ACT3, respectively.

In an embodiment, the formation of the active contacts AC may include forming a metal material (e.g., using a chemical vapor deposition (CVD) process) to fill the active contact trenches ACT and planarizing the metal material to expose the top surface of the second interlayer insulating layer 120.

Referring to FIG. 17C, the first active contact AC1 may be formed to include the first body portion BP1 on the first source/drain pattern SD1, the second body portion BP2 on the second source/drain pattern SD2, and the third body portion BP3 between the first and second body portions BP1 and BP2. The first and second body portions BP1 and BP2 may be formed on the active contact liner AL.

The first air gap AG1 may be formed on the recess region BM_R of the barrier pattern BM. The first air gap AG1 may be interposed between the first active contact AC1 and the device isolation layer ST and between the third body portion BP3 and the device isolation layer ST. The first air gap AG1 may be interposed between the barrier pattern BM and the first active contact AC1 (e.g., between the barrier pattern BM and the third body portion BP3).

The metal material, which is deposited on the protruding portion DP of the active contact liner AL, may be connected to form the first air gap AG1. The metal material may not be formed on the recess region BM_R of the barrier pattern BM.

In some embodiments, a degassing process may be performed, before the PVD process. Air, moisture, and so forth may be removed from the active contact trench ACT by the degassing process. As a result of the degassing process, the first air gap AG1 may be stably formed.

Referring to FIG. 17D, the second active contact AC2 may be formed to include the first body portion BP1 on the first source/drain pattern SD1 of the first PMOSFET region PR1, the second body portion BP2 on the first source/drain pattern SD1 of the first PMOSFET region PR1, and the third body portion BP3 between the first and second body portions BP1 and BP2. The first and second body portions BP1 and BP2 may be formed on the active contact liner AL.

The second air gap AG2 may be formed between the third body portion BP3 and the device isolation layer ST. The second air gap AG2 may be substantially the same as the first air gap AG1 described with reference to FIG. 17C.

Referring back to FIG. 4 and FIGS. 5A to 5E, a gate contact (GC) electrically connected to the gate electrode (GE) may be formed through the second interlayer insulating membrane (120) and the gate capping pattern (GP). The third interlayer insulating layer 130 may be formed on top surfaces of the active contacts AC. The third interlayer insulating layer 130 may be formed on the second interlayer insulating layer 120.

The first metal layer M1 may be formed in the third interlayer insulating layer 130. The fourth interlayer insulating layer 140 may be formed on the third interlayer insulating layer 130. The second metal layer M2 may be formed in the fourth interlayer insulating layer 140.

According to some embodiments of the present disclosure, an air gap may be interposed between a first active contact and a device isolation layer. In more detail, the first active contact may be disposed on a first source/drain pattern and a second source/drain pattern. The first active contact may include a first body portion on the first source/drain pattern, a second body portion on the second source/drain pattern, and a third body portion on the device isolation layer. The air gap may be interposed between the third body portion and the device isolation layer. A conductive material for the first active contact may not be provided in the air gap. Thus, a sectional area of the first active contact may be reduced. Accordingly, a parasitic capacitance between adjacent ones of the active contacts may be reduced, and a semiconductor device with improved electrical characteristics may be provided.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor device, comprising:
a substrate including a first active pattern and a second active pattern, which are spaced apart from each other in a first direction parallel to a top surface of the substrate;
a device isolation layer between the first and second active patterns;
a first source/drain pattern disposed on the first active pattern;
a second source/drain pattern disposed on the second active pattern;
a first active contact disposed on the first and second source/drain patterns;
a barrier pattern interposed between the first active contact and the first source/drain pattern and between the first active contact and the second source/drain pattern and extended into a space between the first active contact and the device isolation layer; and
an air gap interposed between the first active contact and the barrier pattern,
wherein the first active contact is electrically connected to the first and second source/drain patterns.

2. The semiconductor device of claim 1, wherein the air gap is interposed between the first and second source/drain patterns.

3. The semiconductor device of claim 1, wherein the bottommost surface of the first active pattern is spaced apart from the bottommost surface of the barrier pattern in a second direction, and
the second direction is perpendicular to the top surface of the substrate.

4. The semiconductor device of claim 1, wherein a width of the air gap in the first direction is smaller than a width of the first active pattern in the first direction.

5. The semiconductor device of claim 1, wherein a length of the air gap in a second direction is smaller than a length of the first active pattern in the second direction, and
the second direction is perpendicular to the first direction.

6. The semiconductor device of claim 1, wherein a conductivity type of the first source/drain pattern is different from a conductivity type of the second source/drain pattern.

7. The semiconductor device of claim 1, further comprising:
a first channel pattern on the first active pattern;
a second channel pattern on the second active pattern,
wherein the first source/drain pattern is connected to the first channel pattern,
the second source/drain pattern is connected to the second channel pattern, and
each of the first and second channel patterns comprises a plurality of semiconductor patterns stacked on the substrate.

8. The semiconductor device of claim 1, wherein the barrier pattern has a recess region, which is recessed toward the device isolation layer between the first and second source/drain patterns.

9. The semiconductor device of claim 8, wherein the air gap is disposed on the recess region.

10. The semiconductor device of claim 1, wherein the bottommost surface of the air gap is located at a level lower than the bottommost surface of the first active contact.

11. A semiconductor device, comprising:
a substrate including a first active pattern and a second active pattern, which are spaced apart from each other in a first direction parallel to a top surface of the substrate;
a device isolation layer between the first and second active patterns;
a first source/drain pattern disposed on the first active pattern;
a second source/drain pattern disposed on the second active pattern;
a first active contact disposed on the first and second source/drain patterns;
a barrier pattern interposed between the first active contact and the first source/drain pattern and between the first active contact and the second source/drain pattern; and
an air gap interposed between the first active contact and the barrier pattern,
wherein the first active contact comprises:
a first body portion on the first active pattern;
a second body portion on the second active pattern; and
a third body portion on the device isolation layer,
wherein the air gap is interposed between the third body portion and the device isolation layer.

12. The semiconductor device of claim 11, wherein the barrier pattern is extended into a space between the first active contact and the device isolation layer,
the barrier pattern has a recess region, which is recessed toward the device isolation layer between the first and second source/drain patterns, and
the air gap is disposed on the recess region.

13. The semiconductor device of claim 11, wherein the bottommost surface of the air gap is located at a level lower than the bottommost surface of the first active contact.

14. The semiconductor device of claim 11, wherein the bottommost surface of the first body portion is spaced apart from the bottommost surface of the air gap in a second direction, and
the second direction is perpendicular to the top surface of the substrate.

15. The semiconductor device of claim 11, wherein a conductivity type of the first source/drain pattern is the same as a conductivity type of the second source/drain pattern.

16. The semiconductor device of claim 11, wherein a length of the air gap in a second direction is smaller than a length of the first body portion in the second direction, and
the second direction is perpendicular to the top surface of the substrate.

17. A semiconductor device, comprising:
a substrate including a first active pattern and a second active pattern, which are spaced apart from each other in a first direction parallel to a top surface of the substrate;
a device isolation layer between the first and second active patterns;
a first source/drain pattern disposed on the first active pattern;
a second source/drain pattern disposed on the second active pattern;
a first channel pattern disposed on the first active pattern and connected to the first source/drain pattern;
a second channel pattern disposed on the second active pattern and connected to the second source/drain pattern;
a first active contact disposed on the first and second source/drain patterns;
a barrier pattern interposed between the first active contact and the first source/drain pattern and between the first active contact and the second source/drain pattern; and
an air gap interposed between the first active contact and the device isolation layer,
wherein each of the first and second channel patterns comprises a plurality of semiconductor patterns, which are spaced apart from each other in a second direction perpendicular to the top surface of the substrate, and
the first active contact is electrically connected to the first and second source/drain patterns.

18. The semiconductor device of claim 17, wherein the first active contact comprises:
a first body portion on the first active pattern;
a second body portion on the second active pattern; and
a third body portion on the device isolation layer,
wherein the air gap is interposed between the third body portion and the device isolation layer.

19. The semiconductor device of claim 17, wherein a width of the first active contact in the first direction is larger than a width of the air gap in the first direction.

20. The semiconductor device of claim 17, wherein the bottommost surface of the air gap is located at a level lower than the bottommost surface of the first active contact.
